(19) United States
(12) Patent Application Publication
(10) Pub. No.: US 2017/0150239 A1
(43) Pub. Date: May 25, 2017

(54) Wireless Power Metering And Metrics

(71) Applicant: KORTEK INDUSTRIES PTY LTD, Southport, Queensland (AU)

(72) Inventors: Barrie Davis, Sanctuary Cove (AU); Benjamin Davis, Alderley (AU)

(21) Appl. No.: 15/129,819

(22) PCT Filed: Mar. 30, 2015
(86) PCT No.: PCT/AU2015/050136

§ 371 Date: Sep. 27, 2016

(30) Foreign Application Priority Data
Mar. 31, 2014 (AU) 2014901157

(51) Int. Cl. H04Q 9/00; G01R 22/00

(52) U.S. Cl. CPC H04Q 9/00; G01R 22/00; H04Q 2209/40

(57) ABSTRACT

A system (100) for dynamically measuring at least one power metric in a local power circuit and providing the measured power metric to a personal controller (10). The system includes a primary shadow meter (300) with a power measurement module configured to measure a local power circuit and a plurality of ancillary shadow meters (500a, 500b, 500c) that each have a power measurement module configured to measure a single power circuit. The primary shadow meter and ancillary shadow meters may be connected over a wired network and/or wireless network.

### FIELD OF THE INVENTION

The present invention relates to the analysis of real time power metrics in domestic and commercial applications using standard smartphones, tablets, notebooks, laptops, netbooks, ultrabook computers and similar items to act as a communication, processing and human interface for an electricity measurement unit through an adaptable wireless communications link.

### BACKGROUND OF INVENTION

Power meters are a common part of domestic and commercial buildings. In recent years, there has been significant growth in technology used to measure and control mains power through the implementation of devices known as smartmeters. Smartmeters typically incorporate real-time or near real-time sensors that record the consumption of electricity and transfer this data remotely for monitoring and billing purposes. Because smartmeters usually aggregate the total power consumption metrics for an installation, they may not be particularly suited to applications that require more granular measurement or analysis of particular circuits or electrical devices. Moreover, the metrics measured by a smartmeter may not be accessible in real-time by an energy consumer due to the manner in which the data is collected, collated and redistributed. In many instances, a particular installation may be equipped with a simple electromechanical meter incapable of remote data transfer or complex measurement. It can be appreciated that efficient energy management is best served by access to as close to real-time measurement data as possible and that the ability to monitor the health or operating parameters of other critical electrical components may be highly desirable.

In recent years, the proliferation of smartphones has placed powerful computing devices in the hands of the public. While these devices can wirelessly communicate with a range of devices, their generic wireless systems are not compatible with the standards currently used in domestic or commercial smartmeters, meters, switches and circuit breakers, so they cannot natively communicate with such devices in order to exchange information or commands.

### SUMMARY

In one preferred embodiment, the present invention includes three parts: a meter reader with an adaptable wireless communications module operable for wireless communication with a personal controller and a local network communications module operable for communication with a shadow meter; a shadow meter with an adaptable wireless communications module operable for wireless communication with a personal controller and a local network communications module operable for communication with a meter reader or additional shadow meter; and a battery powered personal controller able to wirelessly communicate with a meter reader.

The shadow meter is preferably a measurement or metering device installed into the power wiring after an electricity utility meter in a building, structure or installation and is preferably configured to measure, record and report a broad range of data to an applications program, hereby termed a “Product App”. This may include any combination of parameters, metrics, conditions, specifications and time associated with electricity being consumed on an electrical circuit or by an electrical device, such as, but not limited to: instantaneous voltage, current and power; active, reactive and apparent power; average real power; RMS voltage and current; power factor; line frequency; overcurrent; voltage sag; voltage swell; phase angle; electricity consumed over a defined time period; operational characteristics including any deviation from a specification, limit or base measurement; temperature; service requirements; and/or any other data or metric that may be measured, recorded or stored by the shadow meter. One or more shadow meters may be installed in order to measure and record the power metrics for each desired electrical circuit or electrical device. It can be appreciated that a utility, through the billable utility meter, cannot provide detailed and granular electricity consumption metrics that would enable many domestic, commercial and industrial applications. A shadow meter, by offering instantaneous and real time measurement and reporting of electricity consumption metrics with high accuracy within a building, structure or installation, may facilitate a diverse range of beneficial activities such as monitoring an electrical circuit or equipment on an electrical circuit to: detect any deviation outside safe operating parameters; maintain or action a service record; indentify equipment failure; predict or pre-empt equipment failure; verify a utility bill; sub-billing; measure efficiency gains or losses; perform an energy audit; perform a safety audit; measure a green credential; use in an equipment leasing agreement; and use in relation to a tenancy.

The shadow meter is preferably configured to wirelessly operate: as an adaptable Wi-Fi Direct and network Wi-Fi device, either individually or concurrently, using Wi-Fi-Direct and/or network Wi-Fi technologies; and optionally as a Bluetooth device using Bluetooth SIG class 2.1+EDR or later technologies including Bluetooth Low Energy, Bluetooth 4.X and additional protocols such as CSRMesh. As used herein, “network Wi-Fi” refers to the Wi-Fi Alliance definition as any “wireless local area network (WLAN) products that are based on the Institute of Electrical and Electronic Engineers (IEEE) 802.11 standards” including any amendments, extensions or proprietary implementations. As used herein, the term “Wi-Fi Direct” refers to a device configured to support the Wi-Fi Alliance Wi-Fi Direct specification and amendments, extensions or any proprietary implementations of Wi-Fi peer-to-peer technology.

Wi-Fi Direct and Bluetooth are peer-to-peer capable communication technologies. Peer-to-peer communication methods and control aspects that may be incorporated into the shadow meter are described in more detail in PCT Application No. PCT/AU2011/001666, filed Dec. 29, 2011, titled “Wireless Power, Light and Automation Control,” the entire disclosure of which is incorporated herein by reference. Network Wi-Fi is a communication technology that allows devices to communicate through a WLAN. Adaptable network, peer-to-peer communication methods and system attributes that may be incorporated into the shadow meter are described in more detail in Australian Provisional Application No.2013904180, filed Oct. 29, 2013, titled “Adaptable Multi-Mode Wireless Power, Light and Automation”, and PCT Application No. PCT/AU2012/000959, filed Aug. 15, 2012, titled “Adaptable Wireless Power, Light and Automation System,” the entire disclosures of which are incorporated herein by reference.

The shadow meter preferably includes a physical interface designed to use the mains power wiring in a structure to exchange data with a meter reader and/or any other shadow meters. The shadow meters and/or meter reader preferably communicate by way of power line communications and include the necessary capabilities for impressing a modulated carrier signal onto the mains power wiring. The supported power line communications may be by way of any protocol, standard or specification that facilitates communication between shadow meters and/or meter reader using mains power wiring. In one preferred embodiment, power line communications may incorporate one or more of: any HomePlug Powerline Appliance Homeplug standards or specifications; IEEE 1901, 1901.1 and/or 1901.2 standards or specifications; and/or ITU-T's G.hn standards or specifications; including any amendments, extensions, revisions or proprietary implementations. Other suitable protocols, standards or specifications may include, but are not limited to, those from the Universal Powerline Association, SiConnect, the HD-PLC Alliance, Xsilon and Powerline Intelligent Metering Evolution Alliance. Power line communication, control methods and system attributes that may be incorporated into a shadow meter are described in more detail in PCT Application No. PCT/AU2013/001157, filed Oct. 8, 2013, titled “Wireless Power Control and Metrics” the entire disclosure of which is incorporated herein by reference.

In one preferred embodiment, in addition to, or instead of, power line communications, a shadow meter may preferably include the necessary hardware to support wireless communications with a meter reader and/or other shadow meters via any combination of suitable personal area network (PAN) or home area network (HAN) wireless technologies, protocols, specifications, application profiles or standards including any ZigBee application profile, protocol, standard or specification published by the ZigBee Alliance; any protocol, specification or standard published by the WI-SUN Alliance; any protocol, specification or standard based on IEEE 802.15 including, but not limited to, IEEE 802.15.4; any Z-Wave protocol, specification or standard; any Thread protocol, specification or standard published by the Thread Group Alliance; and/or any protocol, specification or standard based on ANT including ANT+; including any amendments, extensions, revisions or proprietary implementations. Unless otherwise noted, the wireless local network communications capabilities will be described in terms of ZigBee, though the invention is not so limited. ZigBee methods and system attributes that may be incorporated into a shadow meter are described in more detail in PCT Application No. PCT/AU2013/001157, filed Oct. 8, 2013 and in U.S. Application No. 61/786,519, filed Mar. 15, 2013, the entire disclosure of which is incorporated herein by reference.

In one preferred embodiment the shadow meter may form part of a broader energy management system whose methods and system attributes are described in more detail in PCT Application No. PCT/AU2013/001157, filed Oct. 8, 2013.

It can be appreciated that in certain applications it may be desirable for a smartphone to interact with a shadow meter remotely by way of a meter reader. The meter reader is preferably configured to communicate with a shadow meter by way of power line communications and includes the necessary capabilities for impressing a modulated carrier signal onto the mains power wiring. Power line communication, control methods and system attributes that may be incorporated into a shadow meter reader are described in more detail in PCT Application No. PCT/AU2013/001157, filed Oct. 8, 2013. Where desired, the meter reader may preferably communicate with more than one shadow meter by way of a power line communications network.

In one preferred embodiment, in addition to, or instead of, power line communications, the meter reader may preferably include the necessary hardware to support wireless communications with a shadow meter via any combination of suitable personal area network (PAN) or home area network (HAN) wireless technologies, protocols, specifications, application profiles or standards including: any ZigBee application profile, protocol, standard or specification published by the ZigBee Alliance; any protocol, specification or standard published by the WI-SUN Alliance; any protocol, specification or standard based on IEEE 802.15 including, but not limited to, IEEE 802.15.4; any Z-Wave protocol, specification or standard; any Thread protocol, specification or standard published by the Thread Group Alliance; and/or any protocol, specification or standard based on ANT including ANT+; including any amendments, extensions, revisions or proprietary implementations. Unless otherwise noted, the wireless local network communications capabilities will be described in terms of ZigBee, though the invention is not so limited. ZigBee methods and system attributes that may be incorporated into the meter reader are described in more detail in PCT Application No. PCT/AU2013/001157, filed Oct. 8, 2013. Where desired, the meter reader may preferably communicate with more than one shadow meter by way of a wireless PAN or HAN network.

The meter reader is preferably configured to wirelessly operate: as an adaptable Wi-Fi Direct and network Wi-Fi device, either individually or concurrently, using Wi-Fi-Direct and/or network Wi-Fi technologies; and optionally as a Bluetooth device using Bluetooth SIG class 2.1+EDR or later technologies including Bluetooth Low Energy, Bluetooth 4.X and additional protocols such as CSRMesh. Wi-Fi Direct and Bluetooth are peer-to-peer capable communication technologies. Peer-to-peer communication methods and control aspects that may be incorporated into the meter reader are described in more detail in PCT Application No. PCT/AU2011/001666, filed Dec. 29, 2011. Adaptable network, peer-to-peer communication methods and system attributes that may be incorporated into the meter reader are described in more detail in Australian Provisional Application No. 2013904180, filed Oct. 29, 2013, and PCT Application No. PCT/AU2012/000959, filed Aug. 15, 2012.

The personal controller is preferably a commercially available mobile computing device that supports at least network Wi-Fi and may also support Wi-Fi Direct and/or Bluetooth and/or Near Field Communications (NFC). Unless otherwise noted, the personal controller will be described in terms of a smartphone, though the disclosure is not so limited. For example only, the personal controller may be any portable device which can download or install by other means an Applications Program (App), have a suitable interface the user can interact with to control the App in order to execute required functions, and have the wireless communications capability to establish communications with a meter reader or shadow meter. Examples of personal controllers include smartphones, tablets, laptops, smart watches, smart eye wear, ultrabooks and notebook personal computers. The functional elements of a personal controller may be performed by separate devices preferably configured to work in unison as part of a mobile computing platform. By way of example, a smart watch functionally coupled to a smartphone together deliver the functional capabilities of a personal controller through their unison as part of a mobile computing platform.

Depending on the system configuration, a shadow meter can preferably form a communications link with a smartphone using Wi-Fi Direct and/or network Wi-Fi. It can be appreciated that when a shadow meter is connected to a WLAN access point, any smartphone with Wi-Fi capability also connected to the same WLAN access point can use an appropriate App to communicate with the shadow meter. That is, a user can enter a command into their smartphone and send it to the shadow meter via the WLAN access point. In this case the smartphone could be in the vicinity of the WLAN access point, or the smartphone could be at a remote location and communicate with the WLAN access point via the Internet where the WLAN access point is so configured.

It can be appreciated that a shadow meter operating in a Wi-Fi Direct mode can communicate peer-to-peer with a smartphone without the requirement of a WLAN access point. In this case, the shadow meter preferably simulates a Wi-Fi access point, or operates as a software access point (SoftAP), if the smartphone is not using Wi-Fi Direct to communicate; or if the smartphone is using Wi-Fi Direct to communicate, the shadow meter and smartphone can preferably negotiate which device will assume the Wi-Fi Direct group owner role and establish a peer-to-peer connection. Once a peer-to-peer connection has been established, the user is able to exchange data directly between a smartphone and the selected shadow meter without the need for any other intermediary or network.

The present invention in one preferred embodiment provides a shadow meter with wireless communication capabilities derived from any combination and number of integrated circuits, components, memory, microprocessors, aerials, radios, transceivers and controllers that provide both a network Wi-Fi and peer-to-peer Wi-Fi connection, or connections, individually or concurrently. In some preferred embodiments, the shadow meter may also preferably include any combination and number of integrated circuits, components, controllers, transceivers, radios, memory, microprocessors, and aerials to support a wireless Bluetooth connection, or connections. In some preferred embodiments, the shadow meter may preferably include any combination of integrated circuits, components, controllers, transceivers, radios, memory, microprocessors, and aerials to support a wireless PAN or HAN utilizing one or more of ZigBee, Z-wave, ANT, Thread or an alternate wireless network communications protocol, specification or standard.

Depending on cost and desired outcome, the wireless communication capabilities of the shadow meter may be achieved by using: any number and combination of discrete radios, aerials, microprocessors, transceivers, components, integrated circuits and controllers either individually, collectively, or as a system in a package (SiP) or as a system on a chip (SoC); a combination or “combo” chip that aggregates the functionality of a number of discrete transceivers and controllers of different standards as a SiP or SoC; or using a combination of combo chip(s), SiP(s), SoC(s) and/or discrete components, integrated circuits, radios, aerials, transceivers, microprocessors and controllers. The shadow meter may utilize single or multiple wireless bands, physical channels, virtual channels, modes or other coexistence technologies and algorithms, the methods of which are familiar to those of ordinary skill in the art and are not described herein. Depending on the chosen hardware components, the shadow meter may also include shared antenna support and shared signal receiving paths to eliminate the need for an external splitter or reduce the number of aerials required.

The present invention in one preferred embodiment provides a shadow meter with adaptable wireless communications that in a first mode provides a peer-to-peer connection with a smartphone and in a second mode can be configured by the user to operate as a network Wi-Fi device and connect to a WLAN as a client.

The shadow meter preferably has its wireless communications set to initially function in a peer-to-peer mode, preferably utilizing Wi-Fi Direct, irrespective of its final configuration. Because Wi-Fi Direct provides a peer-to-peer connection, as soon as power is applied to the shadow meter, it can be recognised by a smartphone communicating with at least network Wi-Fi and a wireless communications link can be established. A smartphone App is preferably used to configure any operational aspects and control the functional capabilities of the shadow meter. Once a wireless communication link is established, the user is able to activate a smartphone App which preferably uses the data path between the smartphone and shadow meter. Using a smartphone App, the user can choose if the shadow meter is to continue running in peer-to-peer mode, change to network Wi-Fi mode, or run both modes concurrently where supported, and set the shadow meter with any operational parameters required for a network Wi-Fi or peer-to-peer device, name the device, set an encryption key, enter a password and any other requirements that may be required or desirable. When this procedure has been completed, the user can command the shadow meter to “restart”, at which time it will configure itself according to the parameters which have been specified during the setup process.

If the user has chosen the shadow meter to operate in a peer-to-peer mode, preferably utilizing Wi-Fi Direct, it would continue to do so after the restart. The shadow meter would only connect to smartphones that can fully comply with its connection requirements before establishing a direct or peer-to-peer communications link. This may include security measures in addition to any native security measures of Wi-Fi Direct such as Wi-Fi Protected Access or Wi-Fi Protected Access 2.

If the user has chosen the shadow meter to operate in network Wi-Fi mode, the smartphone App would configure the necessary parameters for the shadow meter to connect to a WLAN. When the shadow meter restarts, it would connect as a client device on the WLAN. It would then preferably be accessible to devices which are also connected to the same WLAN. A peer-to-peer wireless mode of the shadow meter is preferably used to configure the necessary parameters for the shadow meter to connect to a WLAN as a client.

In either mode, a smartphone App is preferably used to configure and control the functional capabilities of a shadow meter. In network Wi-Fi mode, the smartphone App communicates with the selected shadow meter via a WLAN access point. In a peer-to-peer mode preferably utilizing Wi-Fi Direct, the smartphone App communicates directly with the selected shadow meter machine to machine.

If the user has chosen the shadow meter to operate in both peer-to-peer mode and network Wi-Fi mode concurrently, when the shadow meter restarts it would appear as a client device on the WLAN and as a Wi-Fi Direct access point/group participant with the functionality of each mode being available. In that way, and as an example only, a shadow meter could allow third parties to control functions or exchange data via a Wi-Fi Direct connection without allowing access to the concurrent WLAN connection, thus preventing access to other WLAN devices.

In one preferred embodiment, a Bluetooth peer-to-peer connection between a smartphone and shadow meter may be used to enter information for configuration of the shadow meter as a network Wi-Fi device and/or Wi-Fi Direct access point/group participant and/or peer-to-peer Wi-Fi device, or to facilitate the establishment of a network Wi-Fi and/or Wi-Fi Direct and/or peer-to-peer Wi-Fi connection. In another preferred embodiment, a Bluetooth connection between a shadow meter and smartphone may be used as a peer-to-peer communication channel to exchange data.

Once a wireless communication link is established between a shadow meter and smartphone, and where the shadow meter is configured with power line communications capabilities, the user is able to activate an App which preferably uses the data path between the smartphone and shadow meter to; join a power line communications network; configure any requirements for the shadow meter to coordinate a power line communications network; or author devices onto a power line communications network. Once a wireless communication link is established between a shadow meter and smartphone, and where the shadow meter is configured with wireless local network communications capabilities, the user is able to activate an App which preferably uses the data path between the smartphone and shadow meter to: join a wireless local communications network; configure any requirements for the shadow meter to coordinate a wireless local communications network; or author devices onto a wireless local communications network.

In addition to configuring the operational aspects of the shadow meter, an App would also preferably be used to process data and/or analyse data and/or compile data and/or exchange data and/or transfer data and/or receive data and/or store data and/or manipulate data and/or display data from a shadow meter or meter reader in any necessary way. Data capabilities of the App may be executed by the smartphone or may integrate an external service platform that utilizes a computer(s), computing device(s) or server(s) in processing data and/or analysing data and/or compiling data and/or exchanging data and/or transferring data and/or sending data and/or receiving data and/or storing data and/or manipulating data, from, or to, the App, which may include tariff, billing, historical and trend data.

Depending on the system configuration, a meter reader can preferably form a communications link with a smartphone using Wi-Fi Direct and/or network Wi-Fi. It can be appreciated that when a meter reader is connected to a WLAN access point, any smartphone with Wi-Fi capability also connected to the same WLAN access point can use an appropriate App to communicate with the meter reader. That is, a user can enter a command into their smartphone and send it to the meter reader via the WLAN access point. In this case the smartphone could be in the vicinity of the WLAN access point, or the smartphone could be at a remote location and communicate with the WLAN access point via the Internet where the WLAN access point is so configured.

It can be appreciated that a meter reader operating in a Wi-Fi Direct mode can communicate peer-to-peer with a smartphone without the requirement of a WLAN access point. In this case, the meter reader preferably simulates a Wi-Fi access point, or operates as a software access point (SoftAP), if the smartphone is not using Wi-Fi Direct to communicate; or if the smartphone is using Wi-Fi Direct to communicate, the meter reader and smartphone can preferably negotiate which device will assume the Wi-Fi Direct group owner role and establish a peer-to-peer connection. Once a peer-to-peer connection has been established, the user is able to exchange data directly between a smartphone and the selected meter reader without the need for any other intermediary or network.

The present invention in one preferred embodiment provides a meter reader with wireless communication capabilities derived from any combination and number of integrated circuits, components, memory, microprocessors, aerials, radios, transceivers and controllers that provide both a network Wi-Fi and peer-to-peer Wi-Fi connection, or connections, individually or concurrently. In some preferred embodiments, the meter reader may also preferably include any combination and number of integrated circuits, components, controllers, transceivers, radios, memory, microprocessors, and aerials to support a wireless Bluetooth connection or connections . . . In some preferred embodiments, the meter reader may preferably include any combination of integrated circuits, components, controllers, transceivers, radios, memory, microprocessors, and aerials to support a wireless PAN or HAN utilizing one or more of ZigBee, Z-wave, ANT, Thread or an alternate wireless network communications protocol, specification or standard.

Depending on cost and desired outcome, the wireless communication capabilities of the meter reader may be achieved by using: any number and combination of discrete radios, aerials, microprocessors, transceivers, components, integrated circuits and controllers either individually, collectively, or as a system in a package (SiP) or as a system on a chip (SoC); a combination or “combo” chip that aggregates the functionality of a number of discrete transceivers and controllers of different standards as a SiP or SoC; or using a combination of combo chip/s, SiP/s, SoC/s and/or discrete components, integrated circuits, radios, aerials, transceivers, microprocessors and controllers. The meter reader may utilize single or multiple wireless bands, physical channels, virtual channels, modes or other coexistence technologies and algorithms, the methods of which would be appreciated by those of ordinary skill in the art and are not described herein. Depending on the chosen hardware components, the meter reader may also include shared antenna support and shared signal receiving paths to eliminate the need for an external splitter or reduce the number of aerials required.

The present invention in one preferred embodiment provides a meter reader with adaptable wireless communications that in a first mode provides a peer-to-peer connection with a smartphone and in a second mode can be configured by the user to operate as a network Wi-Fi device and connect to a WLAN as a client.

The meter reader preferably has its wireless communications set to initially function in a peer-to-peer mode, preferably utilizing Wi-Fi Direct, irrespective of its final configuration. Because Wi-Fi Direct provides a peer-to-peer connection, as soon as power is applied to the meter reader, it can be recognised by a smartphone communicating with at least network Wi-Fi and a wireless communications link can be established. A smartphone App is preferably used to configure any operational aspects and control the functional capabilities of the meter reader. Once a wireless communication link is established, the user is able to activate a smartphone App which preferably uses the data path between the smartphone and meter reader. Using a smartphone App, the user can choose if the meter reader is to continue running in peer-to-peer mode, change to network Wi-Fi mode, or run both modes concurrently where supported, and set the meter reader with any operational parameters required for a network Wi-Fi or peer-to-peer device, name the device, set an encryption key, enter a password and any other requirements that may be required or desirable. When this procedure has been completed, the user can command the meter reader to “restart”, at which time it will configure itself according to the parameters which have been specified during the setup process.

If the user has chosen the meter reader to operate in a peer-to-peer mode, preferably utilizing Wi-Fi Direct, it would continue to do so after the restart. The meter reader would only connect to smartphones that can fully comply with its connection requirements before establishing a direct or peer-to-peer communications link. This may include security measures in addition to any native security measures of Wi-Fi Direct such as Wi-Fi Protected Access or Wi-Fi Protected Access 2.

If the user has chosen the meter reader to operate in network Wi-Fi mode, the smartphone App would configure the necessary parameters for the meter reader to connect to a WLAN. When the meter reader restarts, it would connect as a client device on the WLAN. It would then preferably be accessible to devices which are also connected to the same WLAN. A peer-to-peer wireless mode of the meter reader is preferably used to configure the necessary parameters for the meter reader or shadow meter to connect to a WLAN as a client.

In either mode, a smartphone App is preferably used to configure and control the functional capabilities of the meter reader. In network Wi-Fi mode, the smartphone App communicates with the selected meter reader via a WLAN access point. In peer-to-peer mode preferably utilizing Wi-Fi Direct, the smartphone App communicates directly with the selected meter reader machine to machine.

If the user has chosen the meter reader to operate in both peer-to-peer mode and network Wi-Fi mode concurrently, when the meter reader restarts it would appear as a client device on the WLAN and as a Wi-Fi Direct access point/group participant with the functionality of each mode being available. In that way, and as an example only, a meter reader could allow third parties to control functions via a Wi-Fi Direct connection without allowing access to the concurrent WLAN connection, thus preventing access to other WLAN devices.

In one preferred embodiment, a Bluetooth peer-to-peer connection between a smartphone and meter reader may be used to enter information for configuration of the meter reader as a network Wi-Fi device and/or Wi-Fi Direct access point/group participant and/or peer-to-peer Wi-Fi device, or to facilitate the establishment of a network Wi-Fi and/or Wi-Fi Direct and/or peer-to-peer Wi-Fi connection. In another preferred embodiment, a Bluetooth connection between a meter reader and smartphone may be used as a peer-to-peer communication channel to exchange data.

Once a wireless communication link is established between a meter reader and smartphone, and where the meter reader is configured with power line communications capabilities, the user is able to activate an App which preferably uses the data path between the smartphone and meter reader to: join a power line communications network; configure any requirements for the meter reader to coordinate a power line communications network; or author devices onto a power line communications network. Once a wireless communication link is established between a meter reader and smartphone, and where the meter reader is configured with wireless local network communications capabilities, the user is able to activate an App which preferably uses the data path between the smartphone and meter reader to: join a wireless local communications network; configure any requirements for the meter reader to coordinate a wireless local communications network; or author devices onto a wireless area communications network.

In addition to configuring the operational aspects of the meter reader, an App would also preferably be used to process data and/or analyse data and/or compile data and/or exchange data and/or transfer data and/or receive data and/or store data and/or manipulate data and/or display data from a meter reader or shadow meter in any necessary way.

The shadow meter may have an exposed human interface such as a mechanical switch(s), button(s), or capacitive/proximity touch area(s) that could be used to perform or execute a desired function. The meter reader may have an exposed human interface such as a mechanical switch(s), button(s), or capacitive/proximity touch area(s) that could be used to perform or execute a desired function. In one preferred embodiment, it may be desirable to have no exposed human interface on either device.

The present disclosure in one preferred aspect provides for a device for dynamically measuring at least one power metric in a local power circuit and providing the measured power metric to a personal controller. The device includes a primary shadow meter including a power measurement module for measuring the at least one power metric in the local power circuit, a wireless communications module configured to communicate with the personal controller selectively using at least one peer-to-peer communications standard and a non-peer-to-peer communication standard. The device also includes a local communications module configured to communicate with at least one ancillary shadow meter, and a microcontroller, the microcontroller being configured in a first mode to operate the local communications module using a wired network to communicate with the at least one of the ancillary shadow meter, the microcontroller being configured in a second mode to operate the local communications module using a wireless mesh network to communicate with the at least one of the ancillary shadow meter.

The present disclosure in another preferred aspect provides for a system for dynamically measuring at least one power metric in a local power circuit and providing the measured power metric to a personal controller. The system includes at least one ancillary shadow meter, each ancillary shadow meter including a power measurement module for measuring at least one power metric associated with a single circuit or electrical device, and a local communications module. The system also includes a primary shadow meter including a power measurement module for measuring at least one power metric in the local power circuit, a wireless communications module configured to communicate with the personal controller selectively using at least one peer-to-peer communications standard and a non-peer-to-peer communication standard, and a local communications module configured to communicate with the at least one ancillary shadow meter.

The present disclosure in a further preferred aspect provides for a device for dynamically measuring at least one power metric in a local power network and providing the measured power metric to a personal controller. The device includes a primary shadow meter including a power measurement module for measuring the at least one power metric in the local power network, and a wireless communications module configured to communicate with the personal controller selectively using at least one peer-to-peer communications standard and a non-peer-to-peer communication standard, the primary shadow meter being configured for wiring downstream of an electric utility meter.

### BRIEF DESCRIPTION OF THE DRAWINGS

FIG. 1 is a perspective view of a smartphone for use with a preferred embodiment of the present invention.

FIG. 2 is a block diagram of the functional elements of a shadow meter in accordance with a preferred embodiment of the present invention.

FIG. 3 is a block diagram of the functional elements of a shadow meter in accordance with another preferred embodiment of the present invention.

FIG. 4 is a block diagram of the functional elements of a meter reader in accordance with a preferred embodiment of the present invention.

FIG. 5 is a block diagram of the functional elements of a shadow meter in accordance with another preferred embodiment of the present invention.

FIG. 6 is a diagram of a shadow meter installed in a single phase environment in accordance with another preferred embodiment of the present invention.

FIG. 7 is a diagram of a shadow meter installed in a three phase environment in accordance with another preferred embodiment of the present invention.

FIG. 8 is a system pictorial representation of the smartphone of FIG. 1 and its interaction with the shadow meter of FIG. 3, meter reader of FIG. 4 and shadow meter of FIG. 5.

FIG. 9 is a flow diagram of an exemplary configuration procedure utilizing the smartphone of FIG. 1 to configure the shadow meter of FIG. 2 as a client device in Wi-Fi WLAN of FIG. 8 in accordance with one preferred embodiment of the present disclosure.

### DETAILED DESCRIPTION OF THE DRAWINGS

Alternative embodiments of the invention will be apparent to those of ordinary skill in the art from consideration of the specification and practice of the invention disclosed herein. It is intended that the specification and examples be considered as exemplary only, with a true scope and spirit of the invention being indicated by the claims which follow. It will be understood that the term “comprising” is intended to have a broad, open meaning and not limited to a particular embodiment. The claims as filed and attached with this specification are hereby incorporated by reference into the text of the present description.

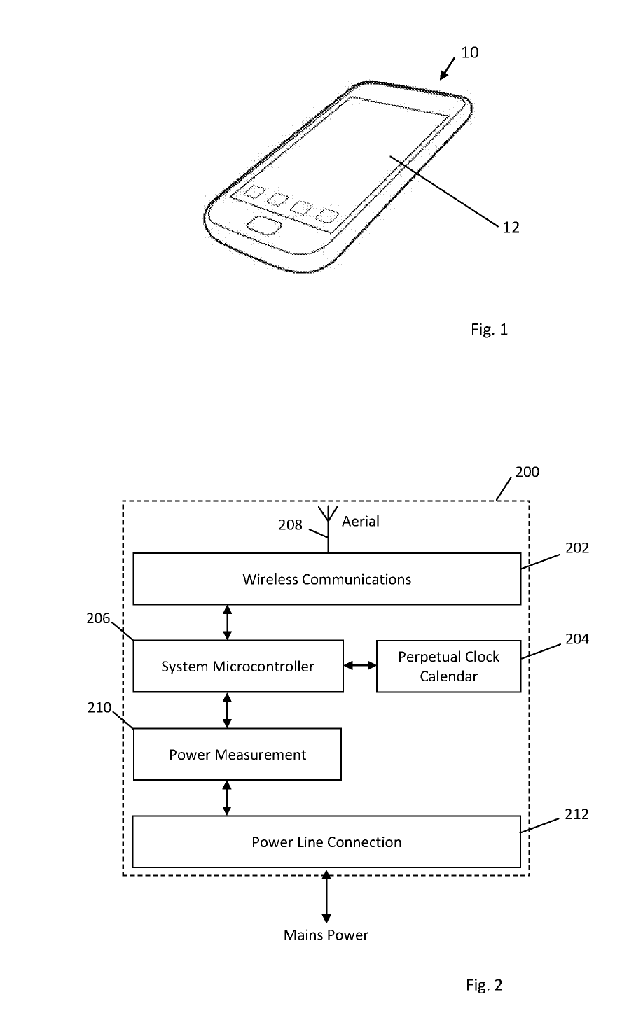

Referring to FIGS. 1 to 8, system 100 preferably includes an applications program, hereby termed a “Product App,” a personal controller 10, one or more shadow meters and a meter reader. It will be understood that when needed, the Product App is always used in combination with one or more processors, and where it is hosted, configures what might otherwise be a general purpose processor into a special purpose processor according to the functions and parameters of the Product App. The Product App may reside in a non-transitory medium such as the processor of a mobile communications device such as a smartphone, in a microprocessor of a system administrator, in a remote, offsite processor, or shared among devices or systems. Preferably, the Product App is downloaded to smartphone 10 and operates as a human interface for the control, configuration, programming and/or interrogation of a shadow meter and/or meter reader.

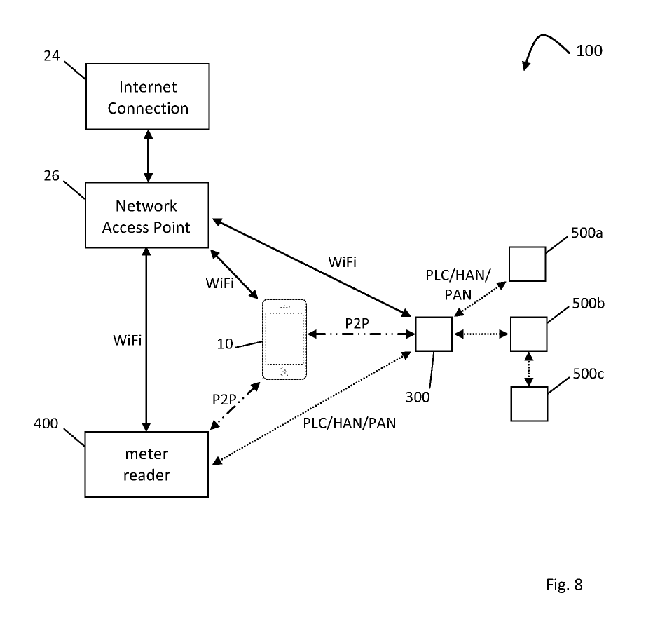

Referring to FIG. 8, system 100 preferably utilises combined wireless communications and power line communications in order to facilitate the exchange of data and commands between smartphone 10, meter reader 400 and at least one shadow meter. The multi-mode communication capabilities of a meter reader and shadow meter allow for a number of complex configurable communication topologies that will be described in further detail below.

FIG. 1 is a perspective representation of a smartphone 10 which uses a wireless link to communicate with a shadow meter and/or meter reader, described in further detail below. Smartphone 10 is preferably a commercially available, conventional smartphone. Some of the basic functions the smartphone preferably includes are: a touch sensitive graphical screen interface 12; a compatible radio transceiver; and the ability to run the Product App specific to the individual smartphone operating system. In the examples that follow, specific coding for the Product App has been omitted for simplicity as a person of ordinary skill in the art would be able to understand and reproduce the functionality of the described embodiments without the need for discussion on particular coding.

Smartphone 10 is preferably configured to operate across a range of wireless communications technologies, including the technology to communicate via at least network Wi-Fi. Smartphone 10 may include additional capability for Wi-Fi Direct and/or Bluetooth and/or NFC. While preferred embodiments of the present invention use a smartphone as its controller, and specifically a smartphone incorporating at least network Wi-Fi, other wireless communications methods and systems could be used depending on the specific requirements of the application of the invention.

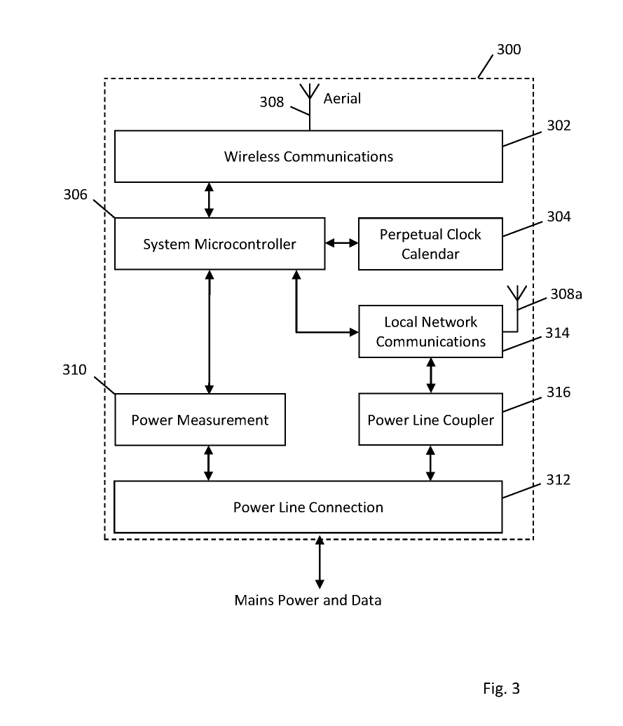

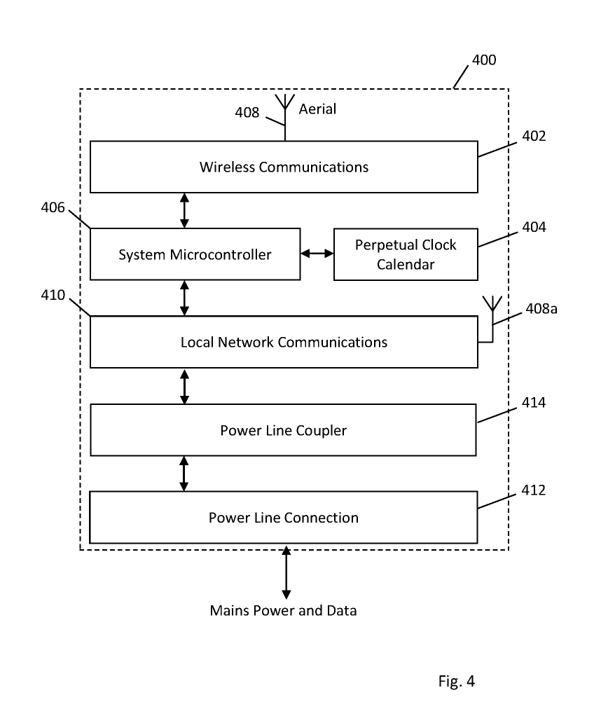

Referring now to FIG. 2, a shadow meter 200 is shown in accordance with a preferred embodiment of the present invention. The shadow meter shown in FIG. 2 generally is an overview of a preferred shadow meter with additional preferred forms of the shadow meter being described in reference to FIGS. 3 and 5, which are exemplarily included in the system shown in FIG. 8. Shadow meter 200 is a physical device that preferably includes wireless communications module 202, perpetual clock calendar 204, system microcontroller 206 with embedded memory, an aerial 208, power measurement module 210, and power line connection 212. In some preferred embodiments, it may be preferable for system microcontroller 206 to support external memory in addition to, or instead of, embedded memory. In some preferred embodiments, it may be preferable for system microcontroller 206 and wireless communications 202 to be fully integrated. Wireless communications 202 includes the circuitry permitting shadow meter 200 to communicate with smartphone 10 and/or other system elements across one or more communications topologies and one or more communication standards, as will be described in further detail below.

Perpetual clock calendar 204 preferably includes a power backup by the way of a battery or supercapacitor enabling real time to be accurately maintained in instances where power is lost. Inclusion of a perpetual clock calendar 204 allows system microcontroller 206 to automatically generate commands; record data; perform a function, measurement or calculation; or exchange data, based on time and/or date. In some preferred embodiments, perpetual clock calendar 204 may be omitted where shadow meter 200 does not perform any time or date dependant operations or receives clock data from an external source via wireless communications. In some preferred embodiments, perpetual clock calendar 204 may be integrated into system microcontroller 206.

Power line connection 212 is preferably the physical interface for connecting shadow meter 200 to the mains power wiring in a building, structure, or installation, and preferably includes the necessary current transformer, resistive voltage divider, potential transformer (voltage transformer) or instrument transformers to appropriately isolate or transform voltage or current levels for the purposes of measurement. An installation can include a dedicated application such as, by way of example only, a dedicated pumping facility. Power line connection 212 may preferably incorporate terminals configured for wiring directly into the mains power of a building, structure or installation. In one preferred embodiment, shadow meter 200 may mount in accordance with a rail standard, such as a DIN rail a standard, alongside circuit breakers or industrial electrical equipment in a typical circuit breaker box. It may be desirable in certain applications to integrate a circuit breaker and shadow meter. In another preferred embodiment, shadow meter 200 may be configured behind a wall mounted panel or integrated into a general purpose outlet (GPO) or three phase power outlet. In another preferred embodiment, power line connection 212 may take the form of a current transformer clamp that preferably wraps around the mains power wiring in a building, structure or installation. It will be appreciated that shadow meter 200 may be configured according to the wiring, connecting, mounting, plug and socket, and current and voltage requirements of various countries and applications without departing from the scope of the present invention. In one preferred embodiment, a shadow meter configured in a physical form as a “wall wart”, or plug in pack with a flying lead, or integrated into an energy consuming device or appliance where a power line connection is configured to plug directly into a mains power general purpose outlet is hereby expressly excluded.

The commands and responses between system microcontroller 206 and smartphone 10 are preferably communicated through a radio frequency wireless link supported by wireless communications 202 and aerial 208. Wireless communications 202 preferably includes any number and combination of integrated circuits, components, controllers, transceivers, radios, memory, microprocessors, and aerials that provide a network Wi-Fi and Wi-Fi peer-to-peer connection individually or concurrently with the ability to optionally support Bluetooth. Examples of wireless communications are described in PCT Application No. PCT/AU2012/000959, filed Aug. 15, 2012. Depending on cost and the desired operational functions, wireless communications 202 may include a Wi-Fi radio, a combination of Wi-Fi radios, or a combination of Wi-Fi Radio(s), wireless radio(s) and a Bluetooth radio. The wireless communication capabilities may be achieved by using: any number and combination of radios, aerials, transceivers, microprocessors, components, integrated circuits and controllers either individually, collectively, or as a system in a package (SiP) or as a system on a chip (SoC); a combination or “combo” chip that aggregates the functionality of a number of transceivers and controllers of different standards as a SiP or SoC; or using any combination of combo chip(s), SiP(s), SoC(s) and/or discrete integrated circuits, radios, aerials, transceivers, microprocessors, memory, components and controllers. Wireless communications may utilize single or multiple wireless bands, physical channels, virtual channels, modes or other coexistence technologies and algorithms, the methods of which are already known to those skilled in the art and are not described herein. Depending on the chosen hardware components, wireless communications 202 may also include shared antenna support and shared signal receiving paths to eliminate the need for an external splitter or reduce the number of aerials required. In one preferred embodiment, wireless communications 202 may be configured to support ZigBee. If desired, an additional aerial or aerials may be added where shared antenna support is not feasible.

When wireless communications 202 operates using a peer-to-peer Wi-Fi specification or standard, preferably Wi-Fi Direct, it can communicate with devices that support network Wi-Fi or Wi-Fi Direct on a peer-to-peer basis without the need for any intermediary hardware. Wireless communications 202 is preferably configured to operate according to the Wi-Fi Direct specification as both a Wi-Fi Direct group participant and Wi-Fi Direct access point or SoftAP, allowing access administrator 200 to appear to devices communicating with network Wi-Fi as a Wi-Fi access point. Through a SoftAP, wireless communications 202 is able to establish a peer-to-peer communications link with a network Wi-Fi device even though the network Wi-Fi device many not support Wi-Fi Direct. In this instance, a device using network Wi-Fi to communicate will receive a device discovery message from an shadow meter 200 as if from a Wi-Fi access point and be able to establish a peer-to-peer communications link with the shadow meter as though it were connecting to a Wi-Fi access point. The procedure of establishing a communications link between a Wi-Fi Direct device and network Wi-Fi devices are defined in the Wi-Fi Alliance Wi-Fi Direct specifications and would be understood by practitioners skilled in communications systems protocols.

Wi-Fi Direct has a number of advantages which simplify communications between a shadow meter and a smartphone. Significant advantages include mobility and portability, where a smartphone and shadow meter only need to be within radio range of each other to establish a wireless communications link. Wi-Fi Direct offers secure communications through means such as Wi-Fi Protected Access (WPA, WPA2) and encryption for transported messages, ensuring the system remains secure to qualified devices. Most importantly, Wi-Fi Direct allows a smartphone with only network Wi-Fi to engage in peer-to-peer data exchange with a shadow meter even where the smartphone network Wi-Fi was never intended to support on-demand, peer-to-peer communications.

As smartphones continue to evolve, new models are starting to include Wi-Fi Direct support in addition to network Wi-Fi. In one preferred embodiment of the present invention, where a shadow meter 200 and smartphone 10 exchange a Wi-Fi Direct intent as part of the discovery process, smartphone 10 and shadow meter 200 will negotiate which device assumes the role of group owner in accordance with the Wi-Fi Alliance Wi-Fi Direct specification, and a peer-to-peer Wi-Fi Direct communication link will be established. The Wi-Fi Direct specification allows any Wi-Fi Direct device to be a group owner, and depending on the capabilities of the device, the negotiation procedure determines the most suitable device to perform this role. Shadow meter 200 in one preferred embodiment may preferably be configured at the highest priority to negotiate a Wi-Fi Direct connection as group owner. By operating as group owner, shadow meter 200 can maintain a number of simultaneous peer-to-peer connections in what is commonly referred to as a hub and spoke arrangement, although it may be desirable in some circumstances to limit the number of open connections to 1:1.

System microcontroller 206 preferably incorporates a firmware program which defines the operation and functions of shadow meter 200 and assumes responsibility for controlling all program code and system elements, including: specifying and controlling the operational modes of wireless communications module 202; control and interrogation of perpetual clock calendar 204; control and interrogation of power measurement module 210; recording any desirable measurements from power measurement module 210 to memory; and facilitating the exchange of data through wireless communications module 202. System microcontroller 206 preferably includes non-volatile memory to store any desirable measurement data, and program data received from the Product App. In some preferred embodiments, the non-volatile memory may be external to system microcontroller 206. In some preferred embodiments, more than one microcontroller may be used.

When shadow meter 200 is manufactured, system microcontroller 206 preferably holds the firmware to operate shadow meter 200 as a network Wi-Fi device and Wi-Fi Direct access point/group participant. When power is applied to shadow meter 200 for the first time, system microcontroller 206 preferably starts wireless communications module 202 in Wi-Fi Direct peer-to-peer mode and begins transmitting discovery messages that can be detected by a smartphone within wireless range.

It can be appreciated that a shadow meter operating as a Wi-Fi Direct access point/group participant can communicate directly with a smartphone without needing a Wi-Fi WLAN. Shadow meter 200 preferably appears as a Wi-Fi access point if smartphone 10 is not using Wi-Fi Direct to communicate; or negotiates with smartphone 10 as to which device will assume a Wi-Fi Direct group owner role if smartphone 10 is using Wi-Fi Direct to communicate. The user is then able to establish a peer-to-peer communications link and send commands directly to the selected shadow meter without the need for any other device.

In one preferred embodiment, wireless communications module 202 in a peer-to-peer mode may be configured to preferably simulate a Wi-Fi access point or operate as a SoftAP without support for Wi-Fi Direct. In that case, a smartphone would preferably establish a peer-to-peer communications link with the shadow meter as if connecting to a Wi-Fi access point, but could not negotiate with the shadow meter a Wi-Fi Direct connection even if smartphone 10 supported Wi-Fi Direct.

A preferred method for controlling a shadow meter is through a related Product App. Installation instructions for the Product App are preferably included with the shadow meter. The Product App preferably adopts the same centralized app store installation methods commonly utilised by conventional smartphone platforms.

The Product App may communicate with any mix of wireless elements and radio technologies that seamlessly provide the best communications link with a shadow meter. The Product App preferably controls smartphone 10 wireless communications in order to initiate, search and establish a wireless communications link with a shadow meter. The Product App may preferably display preconfigured and new shadow meters via graphical elements on smartphone touch screen 12.

When the Product App starts, it will preferably scan for shadow meters and identify any new shadow meter that needs to be initially configured. At this point, if a wireless peer-to-peer connection has not already been established between the smartphone and a new shadow meter, the Product App preferably allows the user to establish a wireless peer-to-peer connection with the desired shadow meter and determine if it is: to operate in peer-to-peer mode and remain a Wi-Fi Direct access point/group participant only; to operate in network Wi-Fi mode and connect to a WLAN as a client and become a network Wi-Fi device; or, where supported by wireless communications module 202, operate concurrently in peer-to-peer mode and network Wi-Fi mode.

In a situation where the smartphone operating system does not allow the Product App to control the smartphone wireless communications in order to establish a peer-to-peer link with a shadow meter, the user may use any mechanism provided by the smartphone to establish a peer-to-peer communication link with a shadow meter prior to starting the Product App.

If the user wants the new shadow meter to run in peer-to-peer mode, preferably utilizing Wi-Fi Direct, they preferably select this option in the Product App. The Product App then leads the user through a series of data inputs using the smartphone's touch screen 12 as a human interface. The Product App communicates with system microcontroller 206 and replaces the general parameters used for the initial connection to specific parameters which define the shadow meter as a unique product. These may include: setting a unique encryption key so all data transfers between the shadow meter and the smartphone are protected; setting the shadow meter name to a unique, easily recognisable identifier; and setting a password in the shadow meter used to establish a secure link with a smartphone.

The Product App preferably maintains a record of these specific parameters in the smartphone memory for future identification of, and connection to, the configured shadow meter.

Once the setup procedure is complete, the Product App preferably commands the shadow meter firmware to reconfigure which may involve a “restart”. When the applications firmware reconfigures, the shadow meter will use the user specified data to populate and create its own unique identity. The smartphone which was used to set this identity will be able to automatically connect to that shadow meter because the new specific parameters are known. Where the smartphone operating system allows, the Product App can then be used to preferably automatically establish a communications link with the shadow meter each time the user selects that particular device in the Product App.

Once a shadow meter has been configured, any other smartphone can only connect with it if the user knows the specific parameters that are now unique to that particular shadow meter. If a second smartphone searches for Wi-Fi access points or Wi-Fi Direct devices, it will see the configured shadow meter with the characteristic that it is “secure”. To connect to it, the user will have to know the specific password allocated to that shadow meter, otherwise it will not be able to establish a communications link. If the password is known and entered into the smartphone when requested, a communication link between the second smartphone and the shadow meter will be established. The Product App is still preferably required to control the shadow meter and this may have additional security measures depending on the nature of the application.

If, instead of configuring the newly installed shadow meter in peer-to-peer mode, the user chooses it to operate in network Wi-Fi mode, this is selected as the required option and the Product App determines if there are one or more WLANs available for the shadow meter to connect to as a client. The Product App requests the user to confirm the preferred network and asks the user to confirm and/or input any necessary network parameters such as the network password so the shadow meter can connect to the WLAN as a client.

The Product App, via the smartphone, communicates with system microcontroller 206 and sets the parameters needed for the shadow meter to establish itself as a network Wi-Fi device which may include any parameters that uniquely identify the shadow meter on the network. When all of the appropriate parameters are known and updated, the Product App commands the shadow meter to reconfigure as a network Wi-Fi device. The shadow meter then connects to the WLAN as a client and is accessible by the smartphone Product App via the WLAN access point. The shadow meter running as a network Wi-Fi client can then be controlled by other smartphones on the same WLAN. In one preferred embodiment, it may be desirable for the shadow meter to include additional security measures such as password protection, a socket layer with the Product App, a hardware authorization chip or other measures to prevent the shadow meter being controlled by other devices on the network without authorization.

Preferably, where the smartphone is configured to determine from a shadow meter's wireless signal that the shadow meter is a new wireless device that can be configured as a WLAN network client, the smartphone preferably allows a user to automatically input the necessary network parameters of a known WLAN network from the smartphone's memory into the shadow meter wirelessly using a peer-to-peer communications link to automatically configure the shadow meter as a network client of the known WLAN network. The smartphone may also preferably be able to determine from the shadow meter's wireless signal a product identifier allowing the smartphone to automatically download the shadow meter's related Product App from the appropriate App store.

Once a shadow meter has been configured as a peer-to-peer device or a network Wi-Fi device, it preferably continues to operate in that mode even after it has been powered off and then on again. All of the specific operating parameters for each mode are preferably saved in the non-volatile memory and are retained if power is removed. When power is restored, system microcontroller 206 powers up in the same Wi-Fi mode that was running before power was removed, and the appropriate firmware and operating parameters are restored from non-volatile memory.

There are applications where a shadow meter running a concurrent peer-to-peer mode and network Wi-Fi mode is desirable. In this situation, the user via the Product App may preferably activate both modes, allowing either mode to be used. Equally, the user, via the Product App, can choose to disable one of the modes, or can change from peer-to-peer mode to network Wi-Fi mode, or vice versa, as desired.

Each time the Wi-Fi mode is changed, the parameters for the new mode are preferably retained by system microcontroller 206 in the event power is disconnected or lost. When power is restored, system microcontroller 206 powers up in the same Wi-Fi mode as previously operating before power was removed, and the appropriate operating parameters are restored from the non-volatile memory. Thus, system microcontroller 206 preferably is configured with an adapted default setting that can be restored from the non-volatile memory.

In one preferred embodiment, wireless communications 202 may be configured with a single Wi-Fi radio that preferably operates in a peer-to-peer mode, utilizing Wi-Fi Direct or simulating a Wi-Fi access point, or in a network Wi-Fi mode. In one preferred embodiment, wireless communications 202 configured with a single Wi-Fi radio may preferably be capable of operating in a peer-to-peer mode, utilizing Wi-Fi Direct or simulating a Wi-Fi access point, and in a network Wi-Fi mode concurrently.

It is envisaged that there may be times when a shadow meter may need to be completely reset. The Product App is preferably able to communicate with the shadow meter and command it to re-initialise to the factory default configuration. In this case, all user-defined parameters that were loaded into the shadow meter unit are lost and it is returned to its factory default state, ready to receive new user-defined parameters.

The shadow meter may incorporate a human interface in the form of a switch(s), button(s), or a capacitive/proximity touch pad(s), which the user could use to cause the shadow meter to: re-initialise to the factory default configuration without the use of a smartphone or Product App; reboot the system; or assist in a Wi-Fi Protected Setup. If desired, the shadow meter may be configured for operation without any manual inputs on the device itself.

In one preferred embodiment, wireless communications 202 may include Bluetooth communication capabilities in addition to Wi-Fi Direct and network Wi-Fi capabilities. A peer-to-peer Bluetooth communication link between smartphone 10 and shadow meter 200 may be used by the Product App to enter parameters for establishing a peer-to-peer Wi-Fi, Wi-Fi Direct or network Wi-Fi communications link, or open a peer-to-peer Wi-Fi, Wi-Fi Direct or network Wi-Fi communications link, or may in its own right operate as a peer-to-peer communications link for exchange of data between the Product App and shadow meter 200. The Product App, the smartphone operating system, or a human interface on shadow meter 200 in the form of touch pad(s), button(s) or switch(s), may facilitate the establishment of a Bluetooth peer-to-peer connection between shadow meter 200 and smartphone 10. The Product App may be configured to allow a user to specify Bluetooth as the preferred peer-to-peer communication method between a shadow meter 200 and smartphone 10. The Bluetooth connection preferably utilizes the secure transmission methods and protocols native to the chosen Bluetooth standard.

Where smartphone 10 and shadow meter 200 use a proprietary implementation of peer-to-peer Wi-Fi, or an adaptation of Wi-Fi Direct, shadow meter 200 and smartphone 10 are preferably configured to use the handshake, negotiation methods, protocols and configuration requirements particular to that proprietary implementation of peer-to-peer Wi-Fi or adaptation of Wi-Fi Direct and may incorporate any hardware, software, firmware or authentication schemes necessary, and may use Bluetooth to facilitate the process where required.

In a preferred form of the present invention, a communications link or mode utilising an ad-hoc IBSS mode of IEEE802.11 (as commonly understood by those of ordinary skill in the art) is hereby expressly excluded.

In one preferred embodiment, the shadow meter may include NFC capability that the Product App could use when first communicating with a new shadow meter to automatically establish a network Wi-Fi, Wi-Fi Direct, Bluetooth or other peer-to-peer communications link on smartphones that support NFC. This process is commonly referred to as “bootstrapping” and is an established method for initializing communications familiar to those skilled in the art.

Referring back to FIG. 2, power measurement module 210 is preferably configured to report a broad range of data to system microcontroller 206. This may include any combination of parameters, metrics, conditions, and specifications associated with electricity being used on an electrical circuit or by an electrical device, such as, but not limited to: instantaneous voltage, current and power; active, reactive and apparent power; average real power; RMS voltage and current; power factor; line frequency; overcurrent; voltage sag; voltage swell; phase angle; and temperature. These metrics may be recorded to memory or utilized by system microcontroller 206 to determine electricity used over a defined time period; operational characteristics including any deviation from a specification, limit or base measurement; temperature; service requirements; and/or any other metric or logical sequencing that could be compiled from the measured, recorded or stored data from power measurement module 210. Any data measured, recorded, stored, calculated, manipulated or complied in a shadow meter can preferably be exchanged with the Product App through wireless communications module 202.

Shadow meter 200 may be configured to include one or more illumination means or visual elements that represent a status or operative element of shadow meter 200. A visual element could be by way of simple light emitting diodes, LCD, colour LCD, an integrated display, or any combination thereof.

While not shown, it may be desirable or necessary in certain situations, such as high voltage applications, to separate power line connection 212, or power line connection 212 and power measurement module 210, into a separate device from shadow meter 200 while remaining functionally coupled by way of a hardwired or wireless means. It can be appreciated that where a wireless means is used, an additional radio or radios may be added to a shadow meter as needed. Where a shadow meter includes a local network communications module, a power line connection separate from the shadow meter, or a power line connection and power measurement module separate from the shadow meter may be configured with a local network communications module utilizing a standard, specification or protocol compatible for communication with a shadow meter's local network communications module.

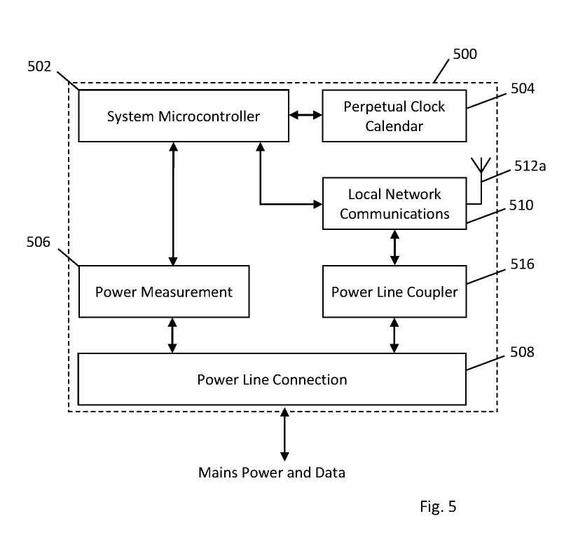

Referring now to FIG. 3, a shadow meter 300 is shown in accordance with another preferred embodiment of the present invention. Shadow meter 300 is preferably configured with the power line connection, power measurement and wireless communication capabilities of shadow meter 200, but includes a local network communications module 314 allowing shadow meter 300 to communicate with a meter reader 400 (FIG. 4) and/or one or more shadow meters across one or more communications topologies and one or more communication standards, as will be described in further detail below.

As shown in FIG. 3, shadow meter 300 is a physical device that preferably includes wireless communications module 302, perpetual clock calendar 304, system microcontroller 306 with embedded memory, aerial 308, power measurement module 310, power line connection 312, local network communications module 314 and power line coupler 316. Where local network communications module 314 includes support for wireless communications, it may preferably include a dedicated aerial 308a. In some preferred embodiments, it may be preferable for system microcontroller 306 to support external memory in addition to, or instead of, embedded memory. In some preferred embodiments, it may be preferable for system microcontroller 306 and local network communications module 314 to be fully integrated, or for system microcontroller 306 and wireless communications module 302 to be fully integrated. Wireless communications module 302 includes the circuitry permitting shadow meter 300 to communicate with smartphone 10 and/or other system elements across one or more communications topologies and one or more communication standards that will be described in further detail below.

Perpetual clock calendar 304, wireless communications module 302, power measurement module 310 and power line connection 312 of shadow meter 300 are preferably configured to provide the same functionality as perpetual clock calendar 204, wireless communications module 202, power measurement module 210 and power line connection 212 of shadow meter 200. For the purposes of brevity, the physical, functional, operational and configuration aspects described for perpetual clock calendar 204, wireless communications module 202, power measurement module 210 and power line connection 212 of shadow meter 200 can preferably be applied to perpetual clock calendar 304, wireless communications module 302, power measurement module 310 and power line connection 312, respectively, of shadow meter 300. Shadow meter 300 preferably differs from shadow meter 200 through the inclusion of additional communication capabilities in the form of local network communications module 314 and system microcontroller 306 being configured to further manage, control, transpose and bridge data passing through multiple communication systems, technologies, specifications, standards and protocols. System microcontroller 306 is preferably configured with the data processing capabilities of system microcontroller 206 in relation to the collection, recording and use of data from power measurement module 310.

System microcontroller 306 preferably incorporates a firmware program which defines the operation and functions of shadow meter 300 and assumes responsibility for controlling all program code and system elements, including: specifying and controlling the operational modes of wireless communications module 302; control and interrogation of perpetual clock calendar 304; control and interrogation of power measurement module 310; specifying and controlling the operational modes of local network communications module 314; facilitating the exchange of data through wireless communications module 302; facilitating the exchange of data through local network communications module 314; and recording any desirable measurements from power measurement module 310 to memory. System microcontroller 306 preferably includes non-volatile memory to store any desirable measurement data or program data received from the Product App. In some preferred embodiments, the non-volatile memory may be external to system microcontroller 306. In some preferred embodiments, more than one microcontroller may be used.

Referring back to FIG. 3, local network communications module 314 preferably includes any number and combination of integrated circuits, components, controllers, digital signal processors, transceivers, memory, microprocessors, SiPs, or SoCs that allow system microcontroller 306 to communicate with a compatible shadow meter and/or meter reader preferably through the mains power wiring of a building using a power line communication protocol, specification or standard. In one preferred embodiment, power line communications may be implemented using a single chip solution with integrated random access memory (RAM), physical layer (PHY), medium access controller (MAC), and analog front end. Local network communications module 314 preferably supports one or more of: the HomePlug Powerline Appliance Homeplug standards or specifications including HomePlug Green PHY or Homeplug AV2; IEEE 1901, 1901.1, 1901.2 standards or specifications; and/or ITU-T's G.hn standards or specifications; including any amendments, extensions, subsets, revisions or proprietary implementations. Other suitable protocols, standards or specifications include, but are not limited to, those from the Universal Powerline Association, SiConnect, the HD-PLC Alliance, Xsilon, and the Powerline Intelligent Metering Evolution Alliance. Local network communications module 314 may be configured to utilize a Smart Energy Profile (SEP) application profile, specification, standard or protocol where desirable.

In one preferred embodiment, instead of, or in addition to, power line communications, local network communications module 314 may preferably include any combination of integrated circuits, radios, aerials, memory, microcontrollers, SiPs, SoCs, transceivers, components or controllers that allow system microcontroller 306 to wirelessly communicate with a compatible shadow meter and/or meter reader via any suitable wireless PAN or HAN mesh standard, protocol or specification including one or more of: any ZigBee protocol, specification, application profile or standard published by the ZigBee Alliance; any ANT protocol, specification or standard; any protocol, specification or standard published by the WI-SUN Alliance; any Z-Wave protocol, specification or standard; any Thread protocol, specification or standard published by the Thread Group Alliance; or any protocol or standard based on IEEE 802.15 including, but not limited to, IEEE 802.15.4; including any amendments, extensions, subsets, revisions or proprietary implementations. Where local network communications module 314 is configured for wireless communications, aerial 308a may be added as needed.

In one preferred embodiment, and without limiting the ability to use any other network topologies or a particular wireless PAN or HAN standard, specification, protocol or methodology, shadow meter 300 may preferably be configured to operate as a ZigBee network coordinator. Using a wireless communication link between smartphone 10 and shadow meter 300, a user via the Product App is preferably able to configure or manage any necessary requirements of a wireless ZigBee network coordinated by shadow meter 300 including the authoring of a meter reader 400 or an additional shadow meter onto the network, the methods of which are well established and would be understood by those of ordinary skill in the art. It can be appreciated that in certain situations it may be preferable for meter reader 400 to operate as a ZigBee coordinator rather than shadow meter 300, in which case shadow meter 300 may preferably operate as a ZigBee router or node on a wireless network coordinated by meter reader 400.

The ZigBee standard defines a comprehensive security architecture and trust management model, which includes encryption, authentication and integrity at each layer of the ZigBee protocol stack, any element of which may be utilized for Zig Bee communications between a shadow meter, meter reader and any additional shadow meters.

Where local network communications module 314 includes support for both power line communications and a wireless mesh standard, system microcontroller 306 or a dedicated microcontroller in local network communications module 314 may communicate using the power line network or wireless mesh network simultaneously, or dynamically assess the most robust communication channel with a meter reader and/or additional shadow meter and use the most robust communication medium in forming a communications link or transferring data down an open communication link. By way of example only, the dynamic assessment of the most robust communication channel may be facilitated by signal detection algorithms for burst transmissions that utilize strength of signal, packet delivery and/or error correction measurements to comparatively determine the most robust communication channel, as would be appreciated by one of ordinary skill in the art.

Because power line communications can travel outside a user's building via the mains power wiring, shadow meter 300 preferably supports encryption for communications with a meter reader 400. Shadow meter 300 and meter reader 400 preferably adopt the standards and/or specifications for security and encryption of data including any passwords, security keys or other secure linking methods that are native to the chosen power line communication protocol, specification or standard.

Referring to FIG. 8, in one preferred embodiment, and without limiting the ability to use any other pairing techniques or topology of a particular power line communications protocol, specification or standard, where shadow meter 300 and meter reader 400 communicate using a HomePlug Powerline protocol, specification or standard, meter reader 400 may preferably ship as an un-associated station and go into a power-on network discovery procedure broadcasting an un-associated identifier message and determining if a Homeplug network is active and can be joined on the mains power wiring of a building.

In order for meter reader 400 to join a secure power line network coordinated by shadow meter 300, meter reader 400 preferably first obtains the network membership key of shadow meter 300. In order to obtain the network membership key, the meter reader is preferably programmed with a unique device access key. Using the wireless communication link between smartphone 10 and shadow meter 300, the user via the Product App preferably enters the unique device access key of meter reader 400 into shadow meter 300. Shadow meter 300 uses the device access key to encrypt its network membership key and broadcast this over the power line network. Since the device access key is unique to meter reader 400, it will be the only new station capable of decrypting the broadcast message from shadow meter 300 in order to retrieve the network membership key. Once meter reader 400 retrieves the network membership key, it can use this to join the power line network coordinated by shadow meter 300. At that point, shadow meter 300 preferably shares with meter reader 400 a network encryption key ensuring all communication between shadow meter 300 and meter reader 400 are encrypted and secure.

The device access key of meter reader 400 may be recorded on the physical unit, or in paperwork or an electronic format associated with the meter reader. The device access key may be recorded in a visually readable from, such as QR code or barcode, allowing the Product App to utilize the smartphone camera to scan and automatically populate the Product App with the device access key. It can be appreciated that a visually readable code may also contain additional information about the functional capability of meter reader 400, allowing the Product App to automatically associate and expose relevant controls for the functional capabilities of the meter reader during configuration. In one preferred embodiment, instead of, or in addition to a visually readable code, meter reader 400 may be configured with an NFC capability allowing for the transfer of the device access key and any additional information to the Product App using near field communications where supported by the smartphone. The device access key may be manually entered into the Product App.

Meter reader 400 and shadow meter 300 may be provided together as a matched set or kit with all networking requirements already preconfigured. For example, the networking membership key and any other necessary networking requirements of shadow meter 300 may be entered by the vendor or manufacturer into meter reader 400, thereby pre-configuring meter reader 400 as an associated station of shadow meter 300 and therefore able to establish a secure power line network as soon as being powered on.

It can be appreciated that other methods of authoring a meter reader onto a power line network coordinated by shadow meter 300 can be used without departing from the scope of the present invention, including methods that may use a human interface such as software or hardware buttons. By way of example only, an asymmetric public/private key encryption method could be utilized by pressing a software button in the Product App while smartphone 10 is wireless connected to shadow meter 300 and pressing a hardware button on meter reader 400, the methods of which would be understood by those of ordinary skill in the art. If desired, shadow meter 300 may include a button, switch or touch pad that could be used to put shadow meter 300 into a secure pairing mode for the purpose of establishing a secure communications link with meter reader 400.

A secure network between shadow meter 300 and meter reader 400 may be limited to shadow meter 300 and meter reader 400 if desired, thereby forming a private secure network. A software, firmware or hardware layer in shadow meter 300 and meter reader 400 may be included to provide an additional security service preventing other devices from communicating with shadow meter 300 or meter reader 400 even if on the same physical layer using the same network membership key or security credentials.

In one preferred embodiment, meter reader 400 may preferably be configured as the power line communications network coordinator instead of the shadow meter. In one preferred embodiment, it may be desirable for the user to configure through the Product App which of shadow meter 300 or meter reader 400 is to be the network coordinator according to the user's preferred topology.

While the application and formation of a secure power line communications network has been described primarily between a shadow meter 300 and meter reader 400, it will be appreciated that the power line communications network is not so limited and may be applied to the formation of a secure communications network between shadow meter 300 and any additional shadow meter for the purpose of allowing communications between more than one shadow meter in an installation.

Referring back to FIG. 3, data is physically modulated onto the mains wiring preferably through power line coupler 316 which preferably includes any necessary isolation or filters.

Shadow meter 300 may be configured to include one or more illumination means or visual elements that represent a status or operative element of shadow meter 300. A visual element could be by way of simple light emitting diodes, LCD, colour LCD, an integrated display, or any combination thereof.

It will be appreciated by those of ordinary skill in the art that the system described above can be varied in many ways without departing from the scope of the present invention. By way of example only, elements of wireless communications module 302, system microcontroller 306, perpetual clock calendar 304 and local network communications module 314 may be aggregated or separated into single components, SoCs or SiPs. For example only, wireless mesh communications such as ZigBee may be added to wireless communications module 302 instead of local network communications module 314. If desired, power line communications and ZigBee wireless communications may be aggregated into a single SoC or SiP. Where wireless communications module 302 is configured to support a wireless mesh network, an additional aerial or aerials may be added where shared antenna support is not feasible.

Referring now to FIG. 4, a meter reader 400 is shown in accordance with a preferred embodiment of the present invention. Meter reader 400 is a physical device that facilitates communication between a smartphone and a shadow meter, or shadow meters, by preferably replicating the wireless communications capabilities of wireless communications 202 or wireless communications 302. Meter reader 400includes wireless communications module 402, perpetual clock calendar 404, system microcontroller 406 with embedded memory, aerial 408, local network communications module 410, power line connection 412 and power line coupler 414. Where local network communications module 410 includes support for wireless communications, it may preferably include a dedicated aerial 408a. In some preferred embodiments, it may be preferable for system microcontroller 406 to support external memory in addition to, or instead of, embedded memory. In some preferred embodiments, it may be preferable for system microcontroller 406 and local network communications module 410 to be fully integrated, or for system microcontroller 406 and wireless communications module 402 to be fully integrated. Wireless communications module 402 includes the circuitry permitting meter reader 400 to communicate with smartphone 10 and/or other system elements across one or more communications topologies and one or more communication standards, as will be described in further detail below.

Perpetual clock calendar 404 preferably includes a power backup by the way of a battery or supercapacitor enabling real time to be accurately maintained in instances where power is lost. Inclusion of a perpetual clock calendar 404 allows system microcontroller 406 to automatically generate commands; record data; perform a function, measurement or calculation; or exchange data, based on time and/or date. In some preferred embodiments, perpetual clock calendar 404 may be omitted where meter reader 400 does not perform any time or date dependant operations or receives clock data from an external source via wireless or power line communications. In some preferred embodiments, perpetual clock calendar 404 may be integrated into system microcontroller 406.

Power line connection 412 is preferably the physical interface for connecting meter reader 400 to the mains power wiring in a building. In one preferred embodiment, power line connection 412 is configured for compatibility with the NEMA 5-15 North American mains power standard allowing meter reader 400 to plug directly into a mains power general purpose outlet. In another preferred embodiment, meter reader 400 may be configured to plug directly in a three phase main power outlet. In another preferred embodiment, meter reader 400 may take the physical form of a fully self-contained plug in pack or “wall wart”. In another preferred embodiment, meter reader 400 may have a flying lead. In another preferred embodiment, power line connection 412 may preferably incorporate a terminal block configured for wiring directly into the mains power of a building or structure. In another preferred embodiment, meter reader 400 may be configured behind a wall mounted panel. In another preferred embodiment, meter reader 400 may be integrated into a general purpose power outlet or be integrated into a light switch. It will be appreciated that the meter reader may be configured according to the plug and socket, and current and voltage requirements of various countries without departing from the scope of the present invention.

The commands and responses between system microcontroller 406 and smartphone 10 are preferably communicated through a radio frequency wireless link supported by wireless communications module 402 and aerial 408. Wireless communications module 402 preferably includes any number and combination of integrated circuits, components, controllers, transceivers, radios, memory, microprocessors, and aerials that provide a network Wi-Fi and Wi-Fi peer-to-peer connection individually or concurrently with the ability to optionally support Bluetooth. Examples of wireless communications are described in PCT Application No. PCT/AU2012/000959, filed Aug. 15, 2012. Depending on cost and the desired operational functions, wireless communications module 402 may include a Wi-Fi radio, a combination of Wi-Fi radios, or a combination of Wi-Fi Radio(s), wireless radio(s) and a Bluetooth radio. The wireless communication capabilities may be achieved by using: any number and combination of radios, aerials, transceivers, microprocessors, components, integrated circuits and controllers either individually, collectively, or as a system in a package (SiP) or as a system on a chip (SoC); a combination or “combo” chip that aggregates the functionality of a number of transceivers and controllers of different standards as a SiP or SoC; or using any combination of combo chip(s), SiP(s), SoC(s) and/or discrete integrated circuits, radios, aerials, transceivers, microprocessors, memory, components and controllers. Wireless communications may utilize single or multiple wireless bands, physical channels, virtual channels, modes or other coexistence technologies and algorithms, the methods of which are already familiar to those skilled in the art and are not described herein. Depending on the chosen hardware components, wireless communications module 402 may also include shared antenna support and shared signal receiving paths to eliminate the need for an external splitter or reduce the number of aerials required. In one preferred embodiment, wireless communications 202 may be configured to support ZigBee. If desired, an additional aerial or aerials may be added where shared antenna support is not feasible.

When wireless communications module 402 operates using a peer-to-peer Wi-Fi specification or standard, preferably Wi-Fi Direct, it can communicate with devices that support network Wi-Fi or Wi-Fi Direct on a peer-to-peer basis without the need for any intermediary hardware. Wireless communications module 402 is preferably configured to operate according to the Wi-Fi Direct specification as both a Wi-Fi Direct group participant and Wi-Fi Direct access point or SoftAP, allowing meter reader 400 to appear to devices communicating with network Wi-Fi as a Wi-Fi access point. Through a SoftAP, wireless communications module 402 is able to establish a peer-to-peer communications link with a network Wi-Fi device even though the network Wi-Fi device many not support Wi-Fi Direct. In this instance, a device using network Wi-Fi to communicate will receive a device discovery message from meter reader 400 as if from a Wi-Fi access point and be able to establish a peer-to-peer communications link with the meter reader as though it were connecting to a Wi-Fi access point. The procedure of establishing a communications link between a Wi-Fi Direct device and network Wi-Fi devices are defined in the Wi-Fi Alliance Wi-Fi Direct specifications and would be understood by practitioners skilled in communications systems protocols.

Wi-Fi Direct has a number of advantages which simplify communications between a meter reader and a smartphone. Significant advantages include mobility and portability, where a smartphone and meter reader only need to be within radio range of each other to establish a wireless communications link. Wi-Fi Direct offers secure communications through means such as Wi-Fi Protected Access (WPA, WPA2) and encryption for transported messages, ensuring the system remains secure to qualified devices. Most importantly, Wi-Fi Direct allows a smartphone with only network Wi-Fi to engage in peer-to-peer data exchange with a meter reader even where the smartphone network Wi-Fi was never intended to support on-demand, peer-to-peer communications.

As smartphones continue to evolve, new models are starting to include Wi-Fi Direct support in addition to network Wi-Fi. In one preferred embodiment of the present invention, where a meter reader 400 and smartphone 10 exchange a Wi-Fi Direct intent as part of the discovery process, smartphone 10 and meter reader 400 will negotiate which device assumes the role of group owner in accordance with the Wi-Fi Alliance Wi-Fi Direct specification, and a peer-to-peer Wi-Fi Direct communication link will be established. The Wi-Fi Direct specification allows any Wi-Fi Direct device to be a group owner, and depending on the capabilities of the device, the negotiation procedure determines the most suitable device to perform this role. Meter reader 400 in one preferred embodiment may preferably be configured at the highest priority to negotiate a Wi-Fi Direct connection as group owner. By operating as group owner, meter reader 400 can maintain a number of simultaneous peer-to-peer connections in what is commonly referred to as a hub and spoke arrangement, although it may be desirable in some circumstances to limit the number of open connections to 1:1.

System microcontroller 406 preferably incorporates a firmware program which defines the operation and functions of meter reader 400 and assumes responsibility for controlling all program code and system elements, including: specifying and controlling the operational modes of wireless communications module 402; control and interrogation of perpetual clock calendar 404; specifying and controlling the operational modes of local network communications module 410; facilitating the exchange of data through wireless communications module 402; and facilitating the exchange of data through local network communications module 410. System microcontroller 406 preferably includes non-volatile memory to store any program data received from the Product App. In some preferred embodiments, the non-volatile memory may be external to system microcontroller 406. In one preferred embodiment, system microcontroller 406 may record any desirable measurements or data reported by a shadow meter, or meters, into memory. In one preferred embodiment, meter reader 400 may operate only as a communication gateway or communication intermediary between a smartphone and shadow meter and not record any measurements or data reported by a shadow meter into memory, except that data necessary for a meter reader and shadow meter to form a communications link. In some preferred embodiments, more than one microcontroller may be used.

When meter reader 400 is manufactured, system microcontroller 406 preferably holds the firmware to operate meter reader 400 as a network Wi-Fi device and Wi-Fi Direct access point/group participant. When power is applied to meter reader 400 for the first time, system microcontroller 406 preferably starts wireless communications module 402 in Wi-Fi Direct peer-to-peer mode and begins transmitting discovery messages that can be detected by a smartphone within wireless range.

It can be appreciated that a meter reader operating as a Wi-Fi Direct access point/group participant can communicate directly with a smartphone without needing a Wi-Fi WLAN. Meter reader 400 preferably appears as a Wi-Fi access point if smartphone 10 is not using Wi-Fi Direct to communicate; or negotiates with smartphone 10 as to which device will assume a Wi-Fi Direct group owner role if smartphone 10 is using Wi-Fi Direct to communicate. The user is then able to establish a peer-to-peer communications link between the smartphone and meter reader and exchange data directly with the selected meter reader without the need for any other device.

In one preferred embodiment, wireless communications module 402 in a peer-to-peer mode may be configured to preferably simulate a Wi-Fi access point or operate as a SoftAP without support for Wi-Fi Direct. In that case, a smartphone would preferably establish a peer-to-peer communications link with the meter reader as if connecting to a Wi-Fi access point, but could not negotiate with the meter reader a Wi-Fi Direct connection even if smartphone 10 supported Wi-Fi Direct.

A preferred method for controlling a meter reader is through a related Product App. Installation instructions for the Product App are preferably included with the meter reader. The Product App preferably adopts the same centralized app store installation methods commonly utilised by conventional smartphone platforms.

The Product App may communicate with any mix of wireless elements and radio technologies that seamlessly provide the best communications link with a meter reader. The Product App preferably controls smartphone 10 wireless communications in order to initiate, search and establish a wireless communications link with a meter reader. The Product App may preferably display preconfigured and new meter readers via graphical elements on smartphone touch screen 12.

When the Product App starts, it will preferably scan for meter readers and identify any new meter reader that needs to be initially configured. At this point, if a wireless peer-to-peer connection has not already been established between the smartphone and a new meter reader, the Product App preferably allows the user to establish a wireless peer-to-peer connection with the desired meter reader and determine if it is: to operate in peer-to-peer mode and remain a Wi-Fi Direct access point/group participant only; to operate in network Wi-Fi mode and connect to a WLAN as a client and become a network Wi-Fi device; or, where supported by wireless communications module 402, operate concurrently in peer-to-peer mode and network Wi-Fi mode.

In a situation where the smartphone operating system does not allow the Product App to control the smartphone wireless communications in order to establish a peer-to-peer link with a meter reader, the user may use any mechanism provided by the smartphone to establish a peer-to-peer communication link with a meter reader prior to starting the Product App.

If the user wants the new meter reader to run in peer-to-peer mode, preferably utilizing Wi-Fi Direct, they preferably select this option in the Product App. The Product App then leads the user through a series of data inputs using the smartphone's touch screen 12 as a human interface. The Product App communicates with system microcontroller 406 and replaces the general parameters used for the initial connection to specific parameters which define the meter reader as a unique product. These may include: setting a unique encryption key so all data transfers between the meter reader and the smartphone are protected; setting the meter reader name to a unique, easily recognisable identifier; and setting a password in the meter reader used to establish a secure link with a smartphone.

The Product App preferably maintains a record of these specific parameters in the smartphone memory for future identification of, and connection to, the configured meter reader.

Once the setup procedure is complete, the Product App preferably commands the meter reader firmware to reconfigure which may involved a “restart”. When the applications firmware reconfigures, the meter reader will use the user specified data to populate and create its own unique identity. The smartphone which was used to set this identity will be able to automatically connect to that meter reader because the new specific parameters are known. Where the smartphone operating system allows, the Product App can then be used to preferably automatically establish a communications link with the meter reader each time the user selects that particular device in the Product App.

Once a meter reader has been configured, any other smartphone can only connect with it if the user knows the specific parameters that are now unique to that particular meter reader. If a second smartphone searches for Wi-Fi access points or Wi-Fi Direct devices, it will see the configured meter reader with the characteristic that it is “secure”. To connect to it, the user will have to know the specific password allocated to that meter reader, otherwise it will not be able to establish a communications link. If the password is known and entered into the smartphone when requested, a communication link between the second smartphone and the meter reader will be established. The Product App is still preferably required to control the meter reader and this may have additional security measures depending on the nature of the application.

If, instead of configuring the newly installed meter reader peer-to-peer mode, the user chooses it to operate in network Wi-Fi mode, this is selected as the required option and the Product App determines if there are one or more WLANs available for the meter reader to connect to as a client. The Product App requests the user to confirm the preferred network and asks the user to confirm and/or input any necessary network parameters such as the network password so the meter reader can connect to the WLAN as a client.

The Product App, via the smartphone, communicates with system microcontroller 406 and sets the parameters needed for the meter reader to establish itself as a network Wi-Fi device which may include any parameters that uniquely identify the meter reader on the network. When all of the appropriate parameters are known and updated, the Product App commands the meter reader to reconfigure as a network Wi-Fi device. The meter reader then connects to the WLAN as a client and is accessible by the smartphone Product App via the WLAN access point. The meter reader running as a network Wi-Fi client can then be controlled by other smartphones on the same WLAN. In one preferred embodiment, it may be desirable for the meter reader to include additional security measures such as password protection, a socket layer with the Product App, a hardware authorization chip or other measures to prevent the meter reader being controlled by other devices on the network without authorization.

Preferably, where the smartphone is configured to determine from a meter reader's wireless signal that the meter reader is a new wireless device that can be configured as a WLAN network client, the smartphone preferably allows a user to automatically input the necessary network parameters of a known WLAN network from the smartphone's memory into the meter reader wirelessly using a peer-to-peer communications link to automatically configure the meter reader as a network client of the known WLAN network. The smartphone may also preferably be able to determine from the meter reader's wireless signal a product identifier allowing the smartphone to automatically download the meter reader's related Product App from the appropriate App store.

Once a meter reader has been configured as a peer-to-peer device or a network Wi-Fi device, it preferably continues to operate in that mode even after it has been powered off and then on again. All of the specific operating parameters for each mode are preferably saved in the non-volatile memory and are retained if power is removed. When power is restored, system microcontroller 406 powers up in the same Wi-Fi mode that was running before power was removed, and the appropriate firmware and operating parameters are restored from non-volatile memory.

There are applications where a meter reader running a concurrent peer-to-peer mode and network Wi-Fi mode is desirable. In this situation, the user via the Product App may preferably activate both modes, allowing either mode to be used. Equally, the user, via the Product App, can choose to disable one of the modes, or can change from peer-to-peer mode to network Wi-Fi mode, or vice versa, as desired.

Each time the Wi-Fi mode is changed, the parameters for the new mode are preferably retained by system microcontroller 406 in the event power is disconnected or lost. When power is restored, system microcontroller 406 powers up in the same Wi-Fi mode as previously operating before power was removed, and the appropriate operating parameters are restored from the non-volatile memory. Thus, system microcontroller 406 preferably is configured with an adapted default setting that can be restored from the non-volatile memory.

In one preferred embodiment, wireless communications 402 may be configured with a single Wi-Fi radio that preferably operates in a peer-to-peer mode, utilizing Wi-Fi Direct or simulating a Wi-Fi access point, or in a network Wi-Fi mode. In one preferred embodiment, wireless communications 402 configured with a single Wi-Fi radio may preferably be capable of operating in a peer-to-peer mode, utilizing Wi-Fi Direct or simulating a Wi-Fi access point, and in a network Wi-Fi mode concurrently.

It is envisaged that there may be times when a meter reader may need to be completely reset. The Product App is preferably able to communicate with the meter reader and command it to re-initialise to the factory default configuration. In this case, all user-defined parameters that were loaded into the meter reader unit are lost and it is returned to its factory default state, ready to receive new user-defined parameters.

The meter reader may incorporate a human interface in the form of a switch(s), button(s), or a capacitive/proximity touch pad(s), which the user could use to cause the meter reader to: re-initialise to the factory default configuration without the use of a smartphone or Product App; reboot the system; or assist in a Wi-Fi Protected Setup. If desired, the meter reader may be configured for operation without any manual inputs on the device itself.

In one preferred embodiment, wireless communications module 402 may include Bluetooth communication capabilities in addition to Wi-Fi Direct and network Wi-Fi capabilities. A peer-to-peer Bluetooth communication link between smartphone 10 and meter reader 400 may be used by the Product App to enter parameters for establishing a peer-to-peer Wi-Fi, Wi-Fi Direct or network Wi-Fi communications link, or open a peer-to-peer Wi-Fi, Wi-Fi Direct or network Wi-Fi communications link, or may in its own right operate as a peer-to-peer communications link for exchange of data between the Product App and meter reader 400. The Product App, the smartphone operating system, or a human interface on meter reader 400 in the form of touch pad(s), button(s) or switch(s), may facilitate the establishment of a Bluetooth peer-to-peer connection between meter reader 400 and smartphone 10. The Product App may be configured to allow a user to specify Bluetooth as the preferred peer-to-peer communication method between a meter reader 400 and smartphone 10. The Bluetooth connection preferably utilizes the secure transmission methods and protocols native to the chosen Bluetooth standard.

Where smartphone 10 and meter reader 400 use a proprietary implementation of peer-to-peer Wi-Fi, or an adaptation of Wi-Fi Direct, meter reader 400 and smartphone 10 are preferably configured to use the handshake, negotiation methods, protocols and configuration requirements particular to that proprietary implementation of peer-to-peer Wi-Fi or adaptation of Wi-Fi Direct and may incorporate any hardware, software, firmware or authentication schemes necessary, and may use Bluetooth to facilitate the process where supported.

In one preferred embodiment, the meter reader may include NFC capability that the Product App could use when first communicating with a new meter reader to automatically establish a peer-to-peer Wi-Fi, network Wi-Fi, Wi-Fi Direct, Bluetooth or other peer-to-peer communications link on smartphones that support NFC. This process is commonly referred to as “bootstrapping” and is an established method for initializing communications known by those skilled in the art.

Meter reader 400 may be configured to include one or more illumination means or visual elements that represent a status or operative element of meter reader 400. A visual element could be by way of simple light emitting diodes, LCD, colour LCD, an integrated display, or any combination thereof.

Referring back to FIG. 4, local network communications module 410 preferably includes any number and combination of integrated circuits, components, controllers, digital signal processors, transceivers, memory, microprocessors, SiPs, or SoCs that allow system microcontroller 406 to communicate with a compatible shadow meter preferably through the mains wiring of a building using a power line communication protocol, specification or standard. In one preferred embodiment, power line communications may be implemented using a single chip solution with integrated random access memory (RAM), physical layer (PHY), medium access controller (MAC), and analog front end. Local network communications module 410 preferably supports one or more of: the HomePlug Powerline Appliance Homeplug standards or specifications including HomePlug Green PHY or Homeplug AV2; IEEE 1901, 1901.1, 1901.2 standards or specifications; and/or ITU-T's G.hn standards or specifications; including any amendments, extensions, subsets, revisions or proprietary implementations. Other suitable protocols, standards or specifications include, but are not limited to, those from the Universal Powerline Association, SiConnect, the HD-PLC Alliance, Xsilon, and the Powerline Intelligent Metering Evolution Alliance. Local network communications may be configured to utilize a Smart Energy Profile (SEP) application profile, specification, standard or protocol where desirable.

In one preferred embodiment, instead of, or in addition to, power line communications, local network communications module 410 may preferably include any combination of integrated circuits, radios, aerials, memory, microcontrollers, SiPs, SoCs, transceivers, components or controllers that allow system microcontroller 406 to wirelessly communicate with a compatible shadow meter via any suitable wireless PAN or HAN mesh standard, protocol or specification including one or more of: any ZigBee protocol, specification, application profile or standard published by the ZigBee Alliance; any Z-Wave protocol, specification or standard; any ANT protocol, specification or standard; any Thread protocol, specification or standard published by the Thread Group Alliance; any protocol, specification or standard published by the WI-SUN Alliance; or any protocol, specification or standard based on IEEE 802.15 including, but not limited to, IEEE 802.15.4; including any amendments, extensions, subsets, revisions or proprietary implementations. Where local network communications module 410 is configured for wireless communications, aerial 408a may be added as required.

In one preferred embodiment, and without limiting the ability to use any other network topologies or a particular wireless PAN or HAN standard, specification, protocol or methodology, meter reader 400 may preferably be configured to operate as a ZigBee network coordinator. Using a wireless communication link between smartphone 10 and meter reader 400, a user via the Product App is preferably able to configure or manage any necessary requirements of a wireless ZigBee network coordinated by meter reader 400 including the authoring of one or more shadow meters onto the network, the methods of which are well established and would be understood by those of ordinary skill in the art. It can be appreciated that in certain situations it may be preferable for a shadow meter to operate as a ZigBee coordinator rather than meter reader 400, in which case meter reader 400 may preferably operate as a ZigBee router or node on the wireless network coordinated by a shadow meter.

Where local network communications module 410 includes support for both power line communications and a wireless mesh communications standard, system microcontroller 406 or a dedicated microcontroller in local network communications module 410 may communicate using the power line network or wireless mesh network simultaneously, or dynamically assess the most robust communication channel with a shadow meter and use the most robust communication medium in forming a communications link or transferring data down an open communication link.

Because power line communications can travel outside a user's building via the mains power wiring, meter reader 400 preferably supports encryption for communications with a shadow meter and preferably adopts the standards and/or specifications for security and encryption of data including any passwords, security keys or other secure linking methods that are native to the chosen power line communication protocol, specification or standard.

In one preferred embodiment, and without limiting the ability to use any other pairing techniques or topology of a particular power line communications protocol, specification or standard, where meter reader 400 and a shadow meter, such as shadow meter 300, communicate using a HomePlug Powerline protocol, specification or standard, the shadow meter may preferably ship as an un-associated station and go into a power-on network discovery procedure broadcasting an un-associated identifier message and determining if a Homeplug network is active and can be joined on the mains power wiring of a building.

In order for a shadow meter to join a secure power line network coordinated by meter reader 400, shadow meter preferably first obtains the network membership key of meter reader 400. In order to obtain the network membership key, the shadow meter is preferably programmed with a unique device access key. Using a wireless communication link between smartphone 10 and meter reader 400, the user via the Product App preferably enters the unique device access key of the shadow meter into meter reader 400. Meter reader 400 uses the device access key to encrypt its network membership key and broadcast this over the power line network. Since the device access key is unique to its associated shadow meter, that shadow meter will be the only new station capable of decrypting the broadcast message from meter reader 400 in order to retrieve the network membership key. Once the shadow meter retrieves the network membership key, it can use this to join the power line network coordinated by meter reader 400. At that point, meter reader 400 preferably shares with the shadow meter a network encryption key ensuring all communication between meter reader 400 and shadow meter 300 are encrypted and secure.

The device access key of a shadow meter may be recorded on the physical unit, or in paperwork or an electronic format associated with the shadow meter. The device access key may be recorded in a visually readable from, such as QR code or barcode, allowing the Product App to utilize the smartphone camera to scan and automatically populate the Product App with the device access key. It can be appreciated that a visually readable code may also contain additional information about the functional capability of a shadow meter, allowing the Product App to automatically associate and expose relevant controls for the functional capabilities of the shadow meter during configuration. In one preferred embodiment, instead of, or in addition to a visually readable code, a shadow meter may be configured with an NFC capability allowing for the transfer of the device access key and any additional information to the Product App using near field communications where supported by the smartphone. The device access key may be manually entered into the Product App.

Meter reader 400 and one or more shadow meters may be provided together as a matched set or kit with all networking requirements already preconfigured. For example, the networking membership key and any other necessary networking requirements of meter reader 400 may be entered by the vendor or manufacturer into one or more shadow meters, thereby pre-configuring the shadow meter(s) as an associated station(s) of meter reader 400 and therefore able to establish a secure power line network as soon as being powered on.

It can be appreciated that other methods of authoring a shadow meter onto a power line network coordinated by meter reader 400 can be used without departing from the scope of the present invention, including methods that may use a human interface such as software or hardware buttons. By way of example only, an asymmetric public/private key encryption method could be utilized by pressing a software button in the Product App while smartphone 10 is wireless connected to meter reader 400 and pressing a hardware button on a shadow meter, the methods of which would be understood by those of ordinary skill in the art. If desired, meter reader 400 may include a button, switch or touch pad that could be used to put meter reader 400 into a secure pairing mode for the purpose of establishing a secure communications link with a shadow meter.

A secure network between meter reader 400 and shadow meter(s) may be limited to the meter reader 400 and shadow meter(s) if desired, thereby forming a private secure network. A software, firmware or hardware layer in meter reader 400 and shadow meter(s) may be included to provide an additional security service preventing other devices from communicating with meter reader 400 or shadow meter(s) even if on the same physical layer using the same network membership key or security credentials.

In one preferred embodiment, it may be desirable for the user to configure through the Product App which of the meter reader 400 or shadow meter is to be the network coordinator according to the user's preferred topology.

Referring back to FIG. 4, data is physically modulated onto the mains wiring preferably through power line coupler 414 which preferably includes any necessary isolation or filters.

Meter reader 400 may be configured to include one or more illumination means or visual elements that represent a status or operative element of meter reader 400. A visual element could be by way of simple light emitting diodes, LCD, colour LCD, an integrated display, or any combination thereof.

Where a meter reader 400 and a shadow meter, such as shadow meter 300, establish a communications link using power line communications or a wireless HAN or PAN, the meter reader and shadow meter are preferably able to exchange data using the communications link. In that way a meter reader 400 may be located remotely from a shadow meter and function as an intermediary or gateway facilitating the exchange of data between a smartphone and shadow meter. Meter reader 400 preferably performs any computational tasks necessary to ensure data from the Product App is transposed into a format compatible with a shadow meter and exchanges the data with the shadow meter using local network communications module 410. Meter reader 400 preferably performs any computational tasks necessary to ensure data from a shadow meter is transposed into a format compatible with the Product App and exchanges the data with the Product App using wireless communications module 402. In that way, meter reader 400 is configured to facilitate two way communications between the Product App and one or more shadow meters.

It will be appreciated by those of ordinary skill in the art that the system described above can be varied in many ways without departing from the scope of the present invention. By way of example only, elements of wireless communications module 402, system microcontroller 406, perpetual clock calendar 404 and local network communications module 410 may be aggregated or separated into single components, SoCs or SiPs. For example only, wireless mesh communications such as ZigBee may be added to wireless communications module 402 instead of local network communications module 410. If desired, power line communications and ZigBee wireless communications may be aggregated into a single SoC or SiP. Where wireless communications module 402 is configured to support a wireless mesh network, an additional aerial or aerials may be added where shared antenna support is not feasible. More than one microcontroller may be used where desirable.

Referring now to FIG. 5, a shadow meter 500 is shown in accordance with another preferred embodiment of the present invention. Shadow meter 500 is a physical device that preferably includes system microcontroller 502 with embedded memory, perpetual clock calendar 504, power measurement 506, power line connection 508, local network communications module 510 and power line coupler 516. Where local network communications module 510 includes support for wireless communications, it may preferably include a dedicated aerial 512a. In some preferred embodiments, it may be preferable for system microcontroller 502 to support external memory in addition to, or instead of, embedded memory. In some preferred embodiments, it may be preferable for system microcontroller 502 and local network communications 510 to be fully integrated. Local network communications module 510 includes the circuitry permitting shadow meter 500 to communicate with meter reader 400 and/or shadow meter 300 and/or other system elements across one or more communications topologies and one or more communication standards.

Shadow meter 500 is preferably configured with the processing, power measurement and local network communication capabilities of shadow meter 300, but preferably does not include an equivalent wireless communications module 302 for communication with a smartphone. In that way, shadow meter 500 is preferably used in conjunction with meter reader 400 and/or shadow meter 300 and would preferably operate as a client, station, node or router of a local communications network coordinated by meter reader 400 or shadow meter 300. By way of example, shadow meter 300 may be configured to communicate with shadow meter 500 through local network communications, allowing a user through wireless communications 302 to use a smartphone and interrogate shadow meter 500 through shadow meter 300 acting as a communications intermediary.

In one preferred embodiment, shadow meter 500 may preferably be configured as the coordinator of a local communications network with meter reader 400 and/or shadow meter 300.

In one preferred embodiment, it may be desirable to hierarchically structure shadow meters according to a primary and ancillary relationship between two or more shadow meters. A primary and ancillary relationship could preferably be formed from different versions, or the same version, of shadow meter. An ancillary shadow meter is preferably a shadow meter configured to communicate with a primary shadow meter using local network communications, the ancillary shadow meter communicating with a smartphone using the primary shadow meter as an intermediary and facilitator. A primary shadow meter is preferably configured to communicate with one or more ancillary shadow meters using local network communications and a smartphone using wireless communications or through meter reader 400. Configuration of the shadow meters may take any form of network topology such as but not limited to, coordinator, node, router, station, client, access point, group owner, group participant, peer, or otherwise, in order to give effect to the primary and ancillary relationship.

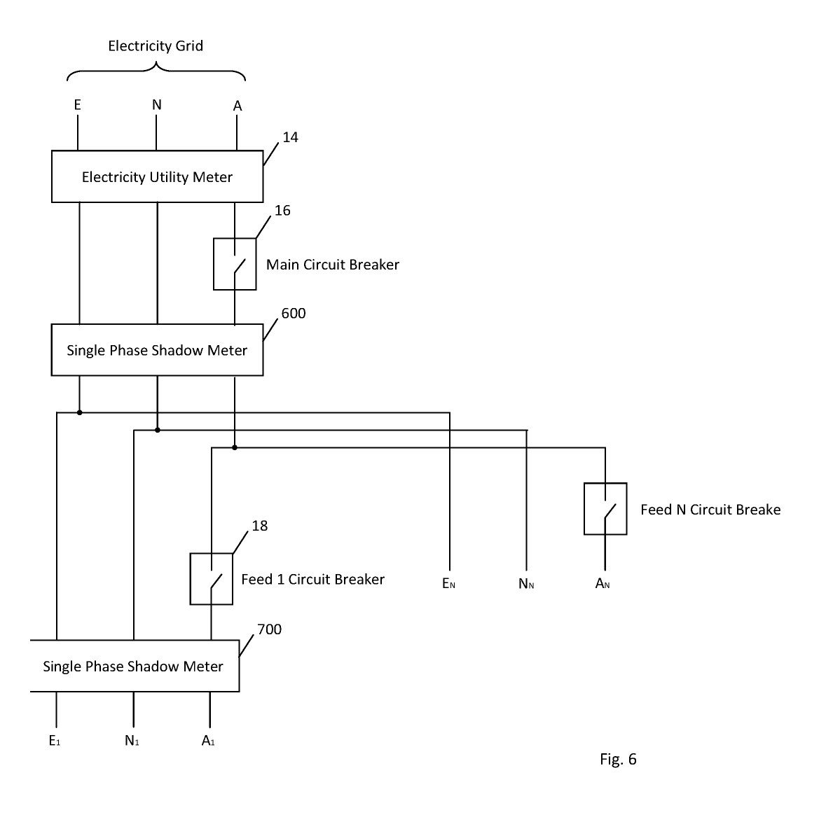

Referring now to FIG. 6, an example wiring of a typical single phase circuit breaker box is shown in accordance with a preferred embodiment of the present invention. Electricity is supplied to a building, structure or installation from the electricity grid as Earth (E), Active (A) and Neutral (N). Electricity utility meter 14 may be any form of metering device for the purposes of recording the billable consumption of electricity, including, but not limited to, a smartmeter, interval meter, or electromechanical meter. It can be appreciated that electricity utility meter 14 may be configured to record the billable consumption of electricity for an entire building, structure or installation, or may be configured to record the billable consumption of electricity for a specific apartment, unit, tenancy, feed or application.

The main power feed preferably includes a main circuit breaker 16 on the active line after electricity utility meter 14. The circuit breaker could be any type of circuit breaker typically used in the power industry, the implementation of which is well established and familiar to those of ordinary skill in the art.

As shown in FIG. 6, a shadow meter 600 is preferably installed after the electricity utility meter 14 and main circuit breaker 16. Shadow meter 600 may be a form of shadow meter 200, shadow meter 300 or shadow meter 500 depending on the desired communication capabilities. Shadow meter 600 is preferably configured with a terminal block having both inputs and outputs that can accommodate E, A, and N wiring. It can be appreciated that shadow meter 600 connected on the main feed would be capable of measuring aggregated metrics across all feeds.

A shadow meter 700 is preferably installed on a feed or wiring circuit after shadow meter 600 and the feed or wiring circuit breaker 18. Shadow meter 700 may be a form of shadow meter 200, shadow meter 300 or shadow meter 500 depending on the desired communication capabilities. Shadow meter 700 is preferably configured with a terminal block having both inputs and outputs that can accommodate E, A, and N wiring. It can be appreciated that because shadow meter 700 is installed on a specific feed or wiring circuit, its measurements and metrics will be for that specific feed or wiring circuit, thereby allowing for a more granular analysis of metrics across multiple feeds or wiring circuits where desired. Additional shadow meters can preferably be added after shadow meter 700 to create a cascading arrangement of meters that further disaggregate and isolate measurements to specific circuits or feeds downstream from shadow meter 700. In one preferred embodiment, a shadow meter may be integrated into the wiring of a building, structure or installation to measure the electricity consumption of a device plugged into a specific power point at the edge of the wiring schematic of a building, structure or installation if so desired. In that way a matrix of shadow meters could be installed providing detailed insight into the energy flows throughout a building, structure or installation.

In one preferred embodiment, shadow meter 600 is preferably configured to measure, record and report power metrics of the same local power circuit or power network of a building, structure or installation as electricity utility meter 14, and to coordinate a local communications network formed from multiple individual ancillary shadow meters 700 which themselves are configured to measure, record and report power metrics for a specific feed or circuit, which may be a single circuit or a device or appliance. Advantages for measuring the power metrics from a number of individual meters include the ability to gain an understanding into the power consumption and operation of various systems (HVAC, lighting (indoor or outdoor)), or different applications in a factory, building or facility, including the ability to break metrics down by tenancy, room or individual appliance. This provides a multi-layered approach to power measurement, not just a single, overall picture, or a measurement of a single device.

Referring to FIGS. 6 and 8, in one preferred embodiment, a desirable configuration may be created by shadow meter 300 performing the role of shadow meter 600 with shadow meter 500 performing the role of shadow meter 700. Shadow meter 300 and shadow meter 500 may preferably communicate with each other by way of local network communications. In that way shadow meter 300 could operate as an intermediary device facilitating the exchange of data between a smartphone and shadow meter 500 via wireless communications module 302. While not shown, meter reader 400 may preferably be configured to communicate with shadow meter 300 by way of local network communications. In that way meter reader 400 could operate as an intermediary device facilitating the exchange of data between a smartphone and shadow meter 500 via wireless communications module 402 and a local network communications link with shadow meter 300, and through shadow meter 300 via a local network communications link with shadow meter 500. It can be appreciated that the local communications network between meter reader 400 and shadow meter 300 may be different to the local communications network between shadow meter 300 and shadow meter 500 by standard, specification, application profile or protocol, coordinator or coexistence. Alternately, all devices could be part of the same local communications network. By way of example, meter reader 400 could operate as an intermediary facilitating the exchange of data between a smartphone and shadow meter 500 directly where meter reader 400 operates as a coordinator of a local network with shadow meter 300 and shadow meter 500 as nodes, routers or stations.

Referring again to FIG. 6, in one preferred embodiment, it may be preferable for shadow meter 600 to be configured as a “master” and communicate with any additional shadow meters, such as shadow meter 700, through a direct hardware interface rather than a local network communications module. In that way shadow meter 700 could be configured without local network communications. This may be desirable to reduce system complexity where all of the shadow meters are grouped within close physical proximity allowing a direct hardwire communications coupling such as in a circuit breaker box.

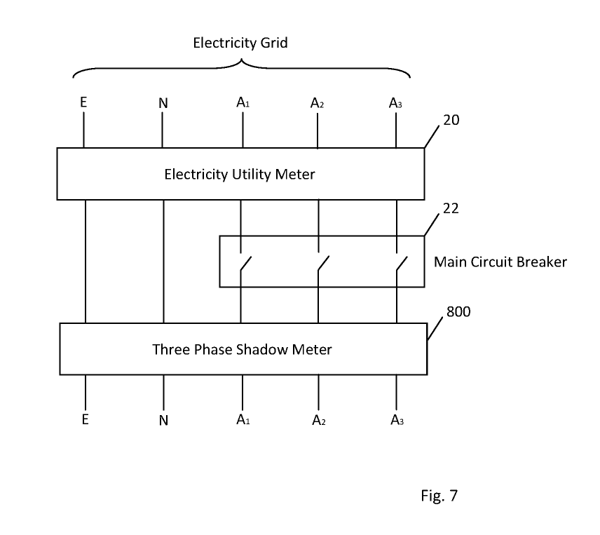

Referring now to FIG. 7, an example wiring of a typical three phase circuit breaker box is shown in accordance with another preferred embodiment of the present invention for the purposes of completeness. Electricity is supplied to a building, structure or installation from the electricity grid as Earth (E), Neutral (N), Active 1 (A1), Active 2 (A2) and Active 3 (A3). Electricity utility meter 20 may be any form of metering device for the purposes of recording the billable consumption of electricity, including, but not limited to, a smartmeter, interval meter, or electromechanical meter. It can be appreciated that electricity utility meter 20 may be configured to record the billable consumption of electricity for an entire building, structure or installation, or may be configured to record the billable consumption of electricity for a specific apartment, unit, tenancy, feed or application.

The main power feed preferably includes a main circuit breaker 22 on across the active line after electricity utility meter 20. The circuit breaker could be any type of circuit breaker typically used in the power industry, the implementation of which is well established and familiar to those of ordinary skill in the art.

Shadow meter 800 is preferably installed after the electricity utility meter 20 and main circuit breaker 22. Shadow meter 800 may be formed as a 3 phase version of shadow meter 200, shadow meter 300 or shadow meter 500 depending on the desired communication capabilities. Shadow meter 800 is preferably configured with a terminal block having both inputs and outputs that can accommodate E, N, A1, A2 and A3 wiring. It can be appreciated that shadow meter 800 connected on the main feed would be capable of measuring aggregated metrics across all feeds. As with the single phase example of FIG. 6, additional shadow meters could be installed across the feeds or wiring circuits in a building, structure or installation as required.

FIG. 8 is a pictorial representation of system 100 showing an exemplary arrangement of smart phone 10, meter reader 400, shadow meter 300, and sub-meters in the form of shadow meters 500a, 500b, and 500c, and the communications systems connecting each of the elements. A Wi-Fi WLAN has an access point 26. Access point 26 has Internet connection 24. Wi-Fi WLAN communications preferably pass through access point 26. Where shadow meter 300 is configured as a network Wi-Fi device, it will preferably operate as a client of access point 26. For smartphone 10 to communicate with shadow meter 300 running as a network Wi-Fi device, smartphone 10 is also preferably connected to access point 26 as a client. Data from smartphone 10 could then pass through access point 26 to shadow meter 300 and vice-versa. If smartphone 10 were not in wireless range of access point 26, it may still be able to communicate with access point 26 via internet connection 24 if so configured. The communications between a smartphone and an access point through an Internet connection would be well understood by those of ordinary skill in the art.

In addition to, or instead of, operating in network Wi-Fi mode, shadow meter 300 may be configured to operate in a peer-to-peer mode, preferably utilizing Wi-Fi Direct or operating as a SoftAP. In that instance, smartphone 10 can wirelessly connect directly to shadow meter 300 without requiring any other device. Accordingly, it can be seen that: (1) access point 26 is not required for peer-to-peer communications; (2) the communications link is formed on an “as needed” basis; and (3) that smartphone 10 needs to be within radio range of shadow meter 300 to establish a direct communications link. Where desirable, a peer-to-peer connection between smartphone 10 and shadow meter 300 could be by way of Bluetooth.

A network Wi-Fi connection and a Wi-Fi Direct peer-to-peer connection offer a different mix of convenience and security. A shadow meter operating as a network Wi-Fi client may be remotely accessed and controlled by a smartphone where access point 26 has an internet connection 24, however the shadow meter then becomes exposed to the outside world and may be vulnerable to external threats such as hacking. Alternatively, a Wi-Fi Direct connection by virtue of its limited wireless range and peer-to-peer architecture offers a higher level of security. The balance between operational modes is usually subjective and dependant on the application at hand. In some instances infrastructure limitations such as the availability of a WLAN may further constrain operational modes.

It can be appreciated that the adaptable nature of wireless communications module 302 and its multi-mode, peer-to-peer and network communications capabilities allow shadow meter 300 to be configured a number of different ways for communications with a smartphone with, or without, the use of a Wi-Fi network. By way of example only, smartphone 10, shadow meter 300 and the Product App may be configured to preferably utilize only those communication pathway(s) that allow for control of a shadow meter without smartphone 10 having to disconnect a WLAN connection with access point 26. In that way, shadow meter 300 may also be configured as a client of access point 26, however it may not always be possible or desirable to configure shadow meter 300 as a client of access point 26. In that instance, communications between smartphone 10 and shadow meter 300 would need to utilize a peer-to-peer communication standard supported by shadow meter 300 and smartphone 10. Where smartphone 10 supports concurrent Wi-Fi Direct and network Wi-Fi, shadow meter 300 and smartphone 10 could preferably form a Wi-Fi Direct communications link, allowing smartphone 10 to remain connected to access point 26 while concurrently connected peer-to-peer to shadow meter 300. Where smartphone 10 does not support Wi-Fi Direct, shadow meter 300 preferably appears as a Wi-Fi access point, however it while it is not usually possible for a smartphone to connect to two access points at the same time, some smartphones are capable of connecting to an access point and a SoftAP or simulated access point at the same time so that smartphone 10 could remain connected to access point 26 and connect to shadow meter 300 simulating a Wi-Fi access point or operating as a SoftAP. Where smartphone 10 cannot connect to access point 26 and a shadow meter 300 simulating a Wi-Fi access point simultaneously, shadow meter 300 may preferably be configured to communicate peer-to-peer with smartphone 10 using Bluetooth.

While not shown, shadow meter 200 can preferably deliver the same network topology through wireless communications module 202 as outlined for shadow meter 300 and wireless communications module 302.

Referring back to FIG. 8 where meter reader 400 is configured as a network Wi-Fi device, it will preferably operate as a client of access point 26. For smartphone 10 to communicate with meter reader 400 running as a network Wi-Fi device, smartphone 10 is also preferably connected to access point 26 as a client. Data from smartphone 10 could then pass through access point 26 to meter reader 400 and vice-versa. If smartphone 10 were not in wireless range of access point 26, it may still be able to communicate with access point 26 via internet connection 24 if so configured.

In addition to, or instead of, operating in network Wi-Fi mode, meter reader 400 may be configured to operate in a peer-to-peer mode preferably utilizing Wi-Fi Direct or operating as a SoftAP. In that instance, smartphone 10 can wirelessly connect directly to meter reader 400 without requiring any other device. Accordingly, it can be seen that: (1) access point 26 is not required for peer-to-peer communications; (2) the communications link is formed on an “as needed” basis; and (3) that smartphone 10 needs to be within radio range of meter reader 400 to establish a direct communications link. Where desirable, a peer-to-peer connection between smartphone 10 and meter reader 400 could be by way of Bluetooth.

It can be appreciated that the adaptable nature of wireless communications module 402 and its multi-mode, peer-to-peer and network communications capabilities allow meter reader 400 to be configured a number of different ways for communications with a smartphone with, or without, the use of a Wi-Fi network.

Shadow meter 200, shadow meter 300 or meter reader 400 may be configured to provide a received signal strength indicator, or received channel power indicator, of access point 26 which shadow meter 200, shadow meter 300 or meter reader 400 may preferably report to the Product App for display on smartphone screen 12. A received signal strength indicator, or received channel power indicator, is a measurement of the power present in a received radio signal and allows a user to locate wireless products such as shadow meter 200, shadow meter 300 or meter reader 400 close enough to access point 26 in order to ensure that a sufficiently strong wireless signal exists between the two devices to provide the best environment for a stable and reliable communications link. The Product App also preferably displays on smartphone screen 12 a received signal strength indicator, or received channel power indicator, for shadow meter 200, shadow meter 300 or meter reader 400 measured by smartphone 10. The Product App may display on smartphone screen 12 a received signal strength indicator, or equivalent, for any shadow meter, such as shadow meter 500, or meter reader on a power line network or wireless local network.

If desired, shadow meter 200, shadow meter 300, shadow meter 500 or meter reader 400 may be configured with a visual indicator capable of displaying a received signal strength indication for any wired or wireless signal that shadow meter 200, shadow meter 300, shadow meter 500 or meter reader 400 may be capable of measuring.

Referring again to FIG. 8, shadow meter 300 preferably communicates with shadow meters 500a, 500b, 500c through mains power lines using power line communications and/or wirelessly via ZigBee. Where shadow meter 300 is configured with the ability to communicate using ZigBee and/or power line communications, and shadow meter 500 supports both ZigBee and/or power line communications, system microcontroller 306 or local network communications 314 preferably includes the ability to dynamically assess the most robust communication channel with shadow meter 500 and use the most robust communication medium in forming a communications link or transferring data down open communication links. Preferably, shadow meter 300 is configured with both ZigBee wireless and power line communications, but only operates using ZigBee wireless communications with those shadow meters or meter readers that only support ZigBee and only operates using power line communications with those shadow meters or meter readers that only support power line communications. Shadow meter 300 may be configured with ZigBee wireless and no power line communications for use with shadow meters or meter readers that only support ZigBee. Shadow meter 300 may be configured with power line communications and no wireless local network communications for use with shadow meters or meter readers that only support power line communications.

Power line networking allows communications between shadow meter 300 and additional shadow meters, such as shadow meter 500, to be routed throughout the power cabling in a building passing through intermediate stations on the way to the recipient station. Because the network is formed by physical wiring, the communication path may not be along a single point to point cable as in many typical wired network structures. Messages are broadcast onto the power lines and travel along all branches of the power line to their intended recipient. Where supported by the chosen power line communications protocol, specification or standard, a shadow meter or station may preferably operate as a repeater of a broadcast signal. By way of example only, shadow meter 300 wishing to exchange data with shadow meter 500c preferably broadcasts that command onto the power lines in a building, structure or installation, the command propagating throughout the power system and potentially passing through other shadow meters operating as repeaters before reaching the intended recipient. Individual shadow meters are identified through a unique address such as a unique MAC identification preferably assigned by the system coordinator at the time of authoring a shadow meter onto the coordinator's secure power line network.

ZigBee networking allows communications between shadow meter 300 and any shadow meters equipped with ZigBee, to be wirelessly routed through intermediate shadow meters operating as routers on the way to the recipient end device in the form of a mesh network. ZigBee mesh methods are already familiar to those skilled in the art and are not described herein.

While not shown, in one preferred embodiment, shadow meter 300 may be configured to communicate with any additional shadow meters through a direct hardware interface rather than a local network communications module as has been already described in relation to FIG. 6. This may be desirable to reduce system complexity where all of the shadow meters are grouped within close physical proximity such as in a circuit breaker box.

Referring again to FIG. 8, meter reader 400 preferably communicates with shadow meters 300, 500a, 500b, 500c through mains power lines using power line communications and/or wirelessly via ZigBee. Where meter reader 400 is configured with the ability to communicate using ZigBee and/or power line communications, and shadow meter 300 supports both ZigBee and/or power line communications, meter reader 400 preferably includes the ability to dynamically assess the most robust communication channel with shadow meter 300 and use the most robust communication medium in forming a communications link or transferring data down open communication links. Such dynamic assessment may be facilitated by the use of one or more strength of signal indicators such as described above. Preferably, meter reader 400 is configured with both ZigBee wireless and power line communications, but only operates using ZigBee wireless communications with those shadow meters that only support ZigBee and only operates using power line communications with those shadow meters that only support power line communications. Meter reader 400 may be configured with ZigBee wireless and no power line communications for use with shadow meters that only support ZigBee. Meter reader 400 may be configured with only power line communications and no wireless local network communications for use with shadow meters that only use power line communications.

Power line networking allows communications between a meter reader and any shadow meter to be routed throughout the power cabling in a building passing through intermediate stations on the way to the recipient station. Where supported by the chosen power line communications protocol specification or standard, each shadow meter or station may preferably operate as a repeater of a broadcast signal from meter reader 400. By way of example only, meter reader 400 wishing to exchange data with shadow meter 500a broadcasts that command onto the power lines in a building, structure or installation, the command propagating throughout the electrical wiring system and potentially passing through other shadow meters, such as shadow meter 300, that may operate as a repeater of the data in order to assist it reaching the intended recipient.

ZigBee networking allows communications between meter reader 400 and any shadow meter equipped with ZigBee to be wirelessly routed through intermediate shadow meters operating as routers or nodes on the way to the recipient end device in the form of a mesh network. ZigBee mesh methods are already known to those skilled in the art and are not described herein.

It can be appreciated that the multi-mode communication capabilities of meter reader 400 and shadow meter 300 support a number of complex network topologies. In one preferred embodiment, shadow meter 300 is preferably configured to coordinate a local communications network using power line communications or ZigBee for shadow meters 500a, 500b and 500c while simultaneously coordinating a separate local communications network using power line communications or ZigBee for meter reader 400. In one preferred embodiment, shadow meter 300 is preferably configured to coordinate a local communications network using power line communications or ZigBee for shadow meters 500a, 500b and 500c while simultaneously coordinating a separate local communications network with meter reader 400 using an application profile, specification, standard or protocol other than that used for the shadow meter network. In one preferred embodiment, shadow meter 300 may be configured to coordinate a power line communications or ZigBee network for one or more shadow meters while coordinating a different power line or ZigBee network for another one or more shadow meters. By way of example only, shadow meter 300 may coordinate a ZigBee wireless network with shadow meter 500a while simultaneously coordinating a power line communications network with shadow meter 500b and 500c. In one preferred embodiment meter reader 400 is preferably configured to coordinate a local communications network using power line communications or ZigBee for shadow meters 300, 500a, 500b and 500c. In one preferred embodiment, shadow meter 300 is preferably configured to coordinate a local communications network using power line communications or ZigBee for shadow meters 500a, 500b and 500c while simultaneously running as a station, router, node or end device of a separate local communications network using power line communications or ZigBee coordinated by meter reader 400. It can be appreciated that aforementioned is by way of example only and that other network topologies are contemplated and may be configured to meet requirements of the application as needed.

Meter reader 400, when used in combination with shadow meter 300, provides a powerful and diverse communications platform. In order for the Product App running on smartphone 10 and shadow meter 300 to communicate, data preferably passes between shadow meter 300 and smartphone 10 either peer-to-peer or via a network access point depending on the chosen configuration of shadow meter 300, or data preferably passes between smartphone 10 and shadow meter 300 through meter reader 400 where meter reader 400 communicates with smartphone 10 either peer-to-peer or via network access point depending on the chosen configuration of meter reader 400, and between meter reader 400 and shadow meter 300 through power line communications or wireless local network communications.

In order to simplify system configuration and reduce cost, it may be desirable to replace shadow meter 300 with shadow meter 500 thereby creating a system where a meter reader 400 would preferably be required to provide a wireless communications interface for smartphone 10 to exchange data with any shadow meter in the network.

Because smartphones do not include native power line communication or ZigBee communication capabilities, they cannot communicate directly with a meter reader or shadow meter communicating via power line or ZigBee communications. Meter reader 400 and/or shadow meter 300 preferably perform any computational tasks necessary to ensure data from the Product App is transposed and communicated in a format compatible with a power line communications network or ZigBee communications network, and that data from shadow meter 300 and/or meter reader 400 is transposed and communicated in a format compatible with the Product App, thereby facilitating two way communications between the Product App, shadow meter 300, meter reader 400 and shadow meter 500 across wireless and physical mediums such as those described above and shown in FIG. 8.

The Product App running on smartphone 10 preferably allows shadow meters to be named and grouped for convenience in the Product App, preferably allowing a single command from the Product App to control a designated group of shadow meters simultaneously. Persons of ordinary skill in the art of network and control will understand that grouping methods and parameters can be stored in the Product App, shadow meter 300, meter reader 400 and/or shadow meter 500 without departing from the scope of the present invention.

If the smartphones are configured with ZigBee wireless communications capabilities, a smartphone 10 may preferably communicate with shadow meter 300, meter reader 400 and/or shadow meter 500 using ZigBee where those devices include ZigBee wireless communications capabilities.

In one preferred embodiment, wireless communications module 202 may be external to shadow meter 200 and configured as a plug in module. In one preferred embodiment, wireless communications module 302 may be external to shadow meter 300 and configured as a plug in module. In one preferred embodiment, wireless communications modules 402 may be external to shadow meter 500 and configured as a plug in module. Methods and system attributes that may be incorporated into a shadow meter or meter reader with modular communications are described in more detail in PCT Application No. PCT/AU2013/000260, filed Mar. 15, 2013, titled “Modular Wireless Power, Light and Automation System” the entire disclosure of which is incorporated herein by reference.

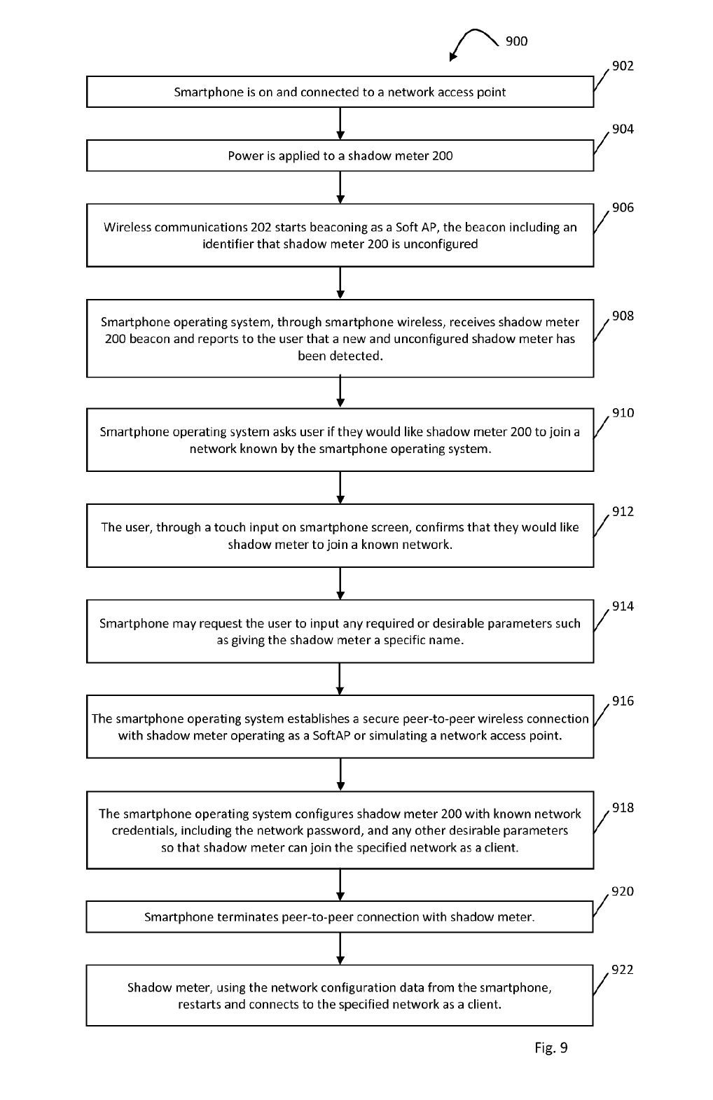

Turning now to FIG. 9, an exemplary configuration procedure 900 is shown for configuration of shadow meter 200 as a network Wi-Fi device by smartphone 10 in a preferred embodiment of the present disclosure. While configuration procedure 900 is described in relation to a smartphone operating system, configuration procedure 900 is not so limited and may be performed by the Product App where the Product App is able to control smartphone wireless communications as required.

At step 902, smartphone 10 is connected to a network access point, such as Wi-Fi network access point 26 in FIG. 8. At step 904 power is applied to shadow meter 200 for the first time, allowing shadow meter 200 to run all of its systems. At step 906, wireless communications module 202, configured to simulate a Wi-Fi network access point or operate as a SoftAP, begins to wirelessly beacon its network information. The wireless beacon preferably includes an identifier that reports shadow meter 200 as an unconfigured Wi-Fi network device to Wi-Fi devices configured to interpret the identifier. At step 908, the smartphone operating system through the smartphone's wireless transceiver, receives shadow meter 200 beacon, determines from the identifier in the beacon that shadow meter 200 is an unconfigured shadow meter and reports to the user via the smartphone touch screen that it has detected a new and unconfigured shadow meter. At step 910, the smartphone operating system asks the user if they would like shadow meter 200 to join a known Wi-Fi network, preferably the network smartphone 10 is currently connected to. At step 912, the user through a touch input on the smartphone screen confirms they would like the unconfigured shadow meter to join a network known by the smartphone operating system.

At step 914, smartphone operating system may require the user to enter a desirable or required parameter, such as a security code used in establishing a communications link between smartphone 10 and system microcontroller 206, or giving unconfigured shadow meter 200 a specific name to be used during configuration as a network client. It can be appreciated that step 914 may be excluded where providing the quickest and easiest mechanism for configuration of a shadow meter 200 by smartphone 10 as a network client of a network known by smartphone 10 is desirable, or where elements of step 914 may be performed after shadow meter 200 is configured and connected to a network as a client, such as giving shadow meter 200 a unique name.

At step 916, the smartphone operating system establishes a secure peer-to-peer Wi-Fi connection with shadow meter 200 preferably configured to simulate a network access point or operate as a SoftAP. The opening of a secure peer-to-peer Wi-Fi connection may include the utilization of authentication hardware, firmware or software integrated into shadow meter 200 and smartphone 10, so that shadow meter 200 may automatically establish a secure connection with smartphone 10 utilizing an authentication handshake without requiring the user to input any security credentials manually. It can be appreciated that where smartphone 10 is unable to support a simultaneous connection with a network access point and a device simulating a Wi-Fi network access point or operating as a SoftAP, such as shadow meter 200, smartphone 10 may disconnect from the Wi-Fi network access point in order to establish a secure peer-to-peer Wi-Fi connection with shadow meter 200.

At step 918, the smartphone operating system configures shadow meter 200 with the network credentials of a known network, including the network password, and any other desirable or necessary parameters so that shadow meter 200 can join the specified network as a network Wi-Fi client device. At step 920, the smartphone operating system terminates the peer-to-peer Wi-Fi connection with shadow meter 200. If the smartphone operating system disconnected from a network access point in order to establish a peer-to-peer Wi-Fi connection with shadow meter 200 at step 916, the smartphone operating system preferably re-establishes a connection with the network access point. At step 922, shadow meter 200, using the network configuration data from the smartphone operating system, configures itself according to the network parameters supplied as a network Wi-Fi device and connects to the specified network access point as a client, after which shadow meter 200 and smartphone 10 are preferably able to communicate with each other through the network access point.

In one preferred embodiment, it may be preferable for shadow meter 200 and smartphone 10 to utilize Wi-Fi Direct in establishing a peer-to-peer connection in configuration procedure 900.

It will be appreciated that certain steps outlined in configuration procedure 900 may be modified, deleted or added without departing from the scope of the present disclosure. For example, configuration procedure 900 may be adapted for execution by the Product App rather than a smartphone operating system. By way of another example, smartphone operating system may cause shadow meter 200 to start its configuration procedure after confirmation by the shadow meter that it has successfully received the network parameters from the smartphone, or system microcontroller 206 of shadow meter 200 may terminate the peer-to-peer connection with the smartphone and start its configuration procedure after successfully receiving network parameters from the smartphone without the smartphone operating system needing to initialize the process.

Exemplary configuration procedure 900 outlined for configuration of shadow meter 200 equally applies to the configuration of shadow meter 300 and meter reader 400.

It will be appreciated by those of ordinary skill in the art that the system described above can be varied in many ways without departing from the scope of the present invention.

For example only, the system may be configured to operate according to ZigBee 3.0, which eliminates communications silos and unifies application profiles into a single universal standard at all levels of a local communications network, especially the application level. Without limiting any networking topologies and security features available in a particular implementation of a ZigBee protocol, standard, specification or application profile, in one preferred embodiment, local network communications of shadow meter 300, shadow meter 500 or meter reader 400 may be configured with ZigBee 3.0 and operate a centralized security network as a coordinator and trust centre, or operate a distributed security network as a router, adding other nodes or routers to the distributed network through association in the exchange of network keys with no coordinator or trust centre and no trust centre link key. Where desirable, security features based on elliptical curve cryptography may be intergraded into ZigBee 3.0 operating on shadow meter 300, shadow meter 500 or meter reader 400 and may be specifically implemented for compatibility with an application standard used by electric utilities such as ZigBee Smart Energy.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A device for dynamically measuring at least one power metric in a local power circuit and providing the measured power metric to a personal controller, the device comprising:
a primary shadow meter including a power measurement module for measuring the at least one power metric in the local power circuit, a wireless communications module configured to communicate with the personal controller selectively using at least one peer-to-peer communications standard and a non-peer-to-peer communication standard, a local communications module configured to communicate with at least one ancillary shadow meter, and a microcontroller, said microcontroller being configured in a first mode to operate said local communications module using a wired network to communicate with said at least one of the ancillary shadow meter, said microcontroller being configured in a second mode to operate said local communications module using a wireless mesh network to communicate with said at least one of the ancillary shadow meter.

2-5. (canceled)

6. The device of claim 1, wherein said wired network uses a power line communications standard.

7. (canceled)

8. The device of claim 1, wherein said wireless mesh network uses a ZigBee communications standard.

9. The device of claim 1, wherein said microcontroller is configured to determine which network is more robust, and operate said local communications module using the most robust network.

10. The device of claim 1, wherein said primary shadow meter is configured as a single phase shadow meter.

11. The device of claim 1, wherein said primary shadow meter is configured as a three-phase shadow meter.

12. The device of claim 1, wherein said microcontroller is configured to open a peer-to-peer wireless communications link with the personal controller by simulating a Wi-Fi access point.

13. A system for dynamically measuring at least one power metric in a local power circuit and providing the measured power metric to a personal controller, the system comprising:
at least one ancillary shadow meter, each ancillary shadow meter including a power measurement module for measuring at least one power metric associated with a single circuit or electrical device, and a local communications module; and
a primary shadow meter including a power measurement module for measuring at least one power metric in the local power circuit, a wireless communications module configured to communicate with the personal controller selectively using at least one peer-to-peer communications standard and a non-peer-to-peer communication standard, and a local communications module configured to communicate with said at least one ancillary shadow meter.

14-17. (canceled)

18. The system of claim 13, wherein said local communications module of said primary shadow meter is configured to communicate with said ancillary shadow meter using a power line communications standard.

19. (canceled)

20. The system of claim 13, wherein said local communications module of said primary shadow meter is configured to communicate with said ancillary shadow meter using a wireless communications standard.

21. The system of claim 20, wherein said wireless communications standard used by said local communications module includes ZigBee.

22. A device for dynamically measuring at least one power metric in a local power network and providing the measured power metric to a personal controller, the device comprising:
a primary shadow meter including a power measurement module for measuring the at least one power metric in the local power network, and a wireless communications module configured to communicate with the personal controller selectively using at least one peer-to-peer communications standard and a non-peer-to-peer communication standard, said primary shadow meter being configured for wiring downstream of an electric utility meter.

23-26. (canceled)

27. The device of claim 22, further comprising at least one ancillary shadow meter configured to measure at least one power metric of a single circuit or electrical device.

28. The device of claim 27, further comprising a local communications module configured to communicate with said ancillary shadow meter using a power line communications standard.

29. (canceled)

30. The device of claim 27, further comprising a local communications module configured to communicate with said ancillary shadow meter using a wireless communications standard.

31. The device of claim 30, wherein said wireless communications standard used by said local communications module includes ZigBee.

32. The device of claim 22, wherein said primary shadow meter is configured as a single phase shadow meter.

33. The device of claim 22, wherein said primary shadow meter is configured as a three-phase shadow meter.

34. The device of claim 22, wherein said primary shadow meter is configured for wiring after a circuit breaker on a power circuit where at least one power metric is dynamically measured.

35. The device of claim 22, wherein said wireless communications module is configured to operate a peer-to-peer wireless communications link with the personal controller by simulating a Wi-Fi access point.
